(19) United States
(12) Patent Application Publication
(10) Pub. No.: US 2021/0388009 A1
(43) Pub. Date: Dec. 16, 2021

(54) ORGANIC METAL-HALIDE PEROVSKITE PRECURSOR, PROCESS FOR PRODUCTION AND USE THEREOF

(71) Applicant: Nanyang Technological University, Singapore (SG)

(72) Inventors: Benny FEBRIANSYAH, Singapore (SG); Teck Ming KOH, Singapore (SG); Prem Jyoti Singh RANA, Singapore (SG); Nripan MATHEWS, Singapore (SG); Subodh Gautam MHAISALKAR, Singapore (SG)

(21) Appl. No.: 17/343,652

(22) Filed: Jun. 9, 2021

(30) Foreign Application Priority Data
Jun. 10, 2020 (SG) 10202005488P

(51) Int. Cl. C07F 7/24; C09D 11/52; C09D 11/037; C09D 11/033

(52) U.S. Cl. CPC C07F 7/24; C09D 11/52; H01G 9/2059; C09D 11/033; C07B 2200/13; C09D 11/037

(57) ABSTRACT

Aspects concern an organic metal-halide perovskite precursor including a divalent metal cation, a halide anion, and an alkylamine, wherein the divalent metal cation is connected to a nitrogen atom of the alkylamine via a covalent bond. Further aspects concern a process for the production of the organic metal-halide perovskite precursor and a perovskite ink including the organic metal-halide perovskite precursor and a non-coordinating solvent.

### CROSS-REFERENCE TO RELATED APPLICATION

This application claims the benefit of priority of Singapore Patent Application No. 10202005488P, filed Jun. 10, 2020, the contents of it being hereby incorporated by reference in its entirety for all purposes.

### TECHNICAL FIELD

An aspect of the disclosure relates to an organic metal-halide perovskite precursor. Another aspect of the disclosure relates to a process for the production of an organic metal-halide perovskite precursor. Another aspect of the disclosure relates to a perovskite ink comprising the organic metal-halide perovskite precursor; and a perovskite structure.

### BACKGROUND

Since its inception as a solar absorber in 2009, three-dimensional (3D) halide perovskites have proven to be successful, witnessing solar cells of over 25% certified power conversion efficiency (PCE). Such success has been made possible by the confluence of the materials' good optoelectronic properties, such as a suitable bandgap, a large absorption coefficient, low exciton binding energies, long electron and hole diffusion lengths with sufficient mobilities, and absence of deep traps in the bandgap. As the consequence, after less than a decade of intense research, halide perovskite solar cells have finally reached a technological maturity. This progress has, however, been accompanied by the use of undesired manufacturing materials, which could become a major barrier to large scale manufacturing.

Therefore, there is a need to provide for improved materials for manufacturing of perovskites.

### SUMMARY

In a first aspect, there is provided an organic metal-halide perovskite precursor. The organic metal-halide perovskite precursor may include a divalent metal cation. The organic metal-halide perovskite precursor may include a halide anion. The organic metal-halide perovskite precursor may include an alkylamine. The divalent metal cation may be connected to a nitrogen atom of the alkylamine via a covalent bond.

In a second aspect, there is provided a process for the production of an organic metal-halide perovskite precursor including a divalent metal cation, a halide anion and an alkylamine, wherein a covalent bond connects the divalent metal cation to a nitrogen atom of the alkylamine. The process may include a) forming a solution including an organic solvent system. The organic solvent system may include a first salt of the divalent metal cation with the halide anion dissolved therein. The organic solvent system may include a second salt of an alkylammonium cation with the halide anion dissolved therein. The organic solvent system may include the alkylamine dissolved therein. The process may further include b) crystallizing the organic metal-halide perovskite precursor from the solution.

In a third aspect, there is provided a perovskite ink including the organic metal-halide perovskite precursor as defined above and a non-coordinating solvent. The organic metal-halide perovskite precursor may be dissolved in the non-coordinating solvent.

In a fourth aspect, there is provided a perovskite. The perovskite may include a divalent metal cation. The perovskite may include a halide anion. The perovskite may include an alkylamine. The perovskite may be prepared from a perovskite ink as defined above.

### BRIEF DESCRIPTION OF THE DRAWINGS

The invention will be better understood with reference to the detailed description when considered in conjunction with the non-limiting examples and the accompanying drawings, in which:

FIG. 1A shows a schematic view of the single crystal X-ray structure of prototypical “2D” organometallic polymer CH₃NH₂—PbI₂ as viewed along the a-direction, ellipsoids are shown at 50% probability;

FIG. 1B shows Powder X-Ray Diffraction (PXRD) patterns of bulk CH₃NH₂—PbI₂ at room temperature (RT), for comparison, the simulated RT PXRD pattern is included;

FIG. 1C shows the ²⁰⁷Pb solid-state nuclear magnetic resonance (NMR) spectra of CH₃NH₂—PbI₂ (top) and PbI₂ (bottom), under magnetic-angle spinning (MAS) frequencies of 15 and 12 KHz respectively, alongside their simulated line-shapes;

FIG. 1D shows the Fourier-transform infrared (FT-IR) spectrum of CH₃NH₂—PbI₂ (top) in comparison to that of PbI₂ (bottom);

FIG. 2A shows vials of perovskite precursors CH₃NH₃I:PbI₂ (1:1 molar ratio) in acetonitrile (ACN) (left, 100 mM), and CH₃NH₃I:CH₃NH₂—PbI₂ (1:1 molar ratio) in ACN (right, 100 mM);

FIG. 2B is a schematic illustration showing faster dissolution of CH₃NH₃I:CH₃NH₂—PbI₂ in ACN due to release of CH₃NH₂ gas carried by CH₃NH₂—PbI₂;

FIG. 2C is a photograph of 10×10 cm² MAPbI₃ film deposited from the precursor ink containing CH₃NH₂—PbI₂;

FIG. 3A is a schematic illustration of perovskite formation process based on precursor ink based on CH₃NH₂—PbI₂;

FIG. 3B is a schematic diagram of the planar perovskite solar cell structure implemented in our study;

FIG. 3C shows the power conversion efficiency (PCE) distribution of solar cells fabricated from precursor ink based on CH₃NH₂—PbI₂;

FIG. 3D shows the J-V characteristics (straight, dotted, and dashed lines represent reverse, forward, and dark current of the device, respectively);

FIG. 3E shows the incident-to-photon-efficiency (IPCE) spectrum and integrated current density of the best performing device fabricated from ink based on CH₃NH₂—PbI₂;

FIG. 3F shows the light-intensity-dependent J_{SC} behavior of the corresponding best performing solar cell;

FIG. 3G shows the light-intensity-dependent V_{OC} behavior of the corresponding best performing solar cell;

FIG. 4A shows the surface morphology of Field Emission Scanning Electron Microscope (FE-SEM) images of the perovskite films deposited from the precursor ink containing CH₃NH₂—PbI₂;

FIG. 4B shows the corresponding grain size distribution of the resulting perovskite crystallites where D̅ represents the average grain size;

FIG. 4C shows a cross-sectional view of FE-SEM images of the perovskite films deposited from the precursor ink containing CH₃NH₂—PbI₂;

FIG. 4D shows the Glancing Angle X-Ray Diffraction (GAXRD) patterns of the fabricated perovskite film—inset shows the (100) peak of 2θ=ca. 14.14°;

FIG. 4E shows the ultraviolet-visible (UV-vis) absorption and photoluminescence (PL) of the fabricated perovskite film;

FIG. 4F shows the time-resolved PL decay spectra of the fabricated perovskite film;

FIG. 5 shows the Glass Transition Temperature (TG) curve of CH₃NH₂—PbI₂. Mass loss at ca. 100° C. is owing to the release of CH₃NH₂ molecule, while the mass loss at ca. 450° C. is attributed to degradation of PbI₂;

FIG. 6 is a photograph of single crystals CH₃NH₂—PbI₂ grown in a bulk, which yielded around 25 g of solids, as shown in the right;

FIG. 7 shows a low wavenumber Raman spectra of CH₃NH₂—PbI₂ recorded at RT;

FIG. 8 shows an RT MAS ¹³C solid state (SS) NMR spectrum of CH₃NH₂—PbI₂; with resonances at 29 and 31 ppm reported for methyl ammonium iodide (MAI) and MAPbI₃, respectively; the downfield shift suggests that, relative to ammonium group, the bonding with Pb²⁺ by the nitrogen (N) atom results in a more withdrawing environment for the carbon (C) atom in CH₃ functionality;

FIG. 9 shows a high wavenumber Raman spectrum of CH₃NH₂—PbI₂ recorded at RT (dotted line)—in comparison, the RT Raman spectrum corresponding to that of CH₃NH₃I (straight line) is also included;

FIG. 10 is a ¹³C {¹H} NMR spectra of CD₃CN solutions containing pristine MAI (top) and CH₃NH₂—PbI₂ plus MAI (bottom) where downfield shift of methyl group is observed in the latter; consistent with the previous ¹³C solid SSNMR spectra (FIG. 6), such shift suggests that CH₃NH₂ binding with Pb²⁺ also occurs in solution that results in more electron withdrawing environment for the C atom;

FIG. 11 shows absorption spectra of solutions containing CH₃NH₃I:CH₃NH₂—PbI₂ (1:1 molar ratio) in ACN in different concentrations. The experiments were kept at 1.5 mM to prevent saturation of the signal at high energy region, such that the ratio between each of the peaks can be seen clearly;

FIG. 12 shows a mass spectrum of CH₃NH₃I:CH₃NH₂—PbI₂ (1:1 molar ratio) in ACN (1.5 mM), revealing huge disparity between [I]⁻ and [PbI₃]⁻ species inside of the solution; insets are zoomed in [PbI₃]⁻ peaks along with the corresponding simulated patterns;

FIG. 13 are photographs of bubbling processes of using [Pb(CH₃NH₂)I₂]ₙ as a precursor (top) in comparison to that of pure PbI₂ (bottom);

FIG. 14A and FIG. 14B are photographs of perovskite films of 10×10 cm² dimensions deposited from precursor ink prepared from CH₃NH₂—PbI₂;

FIG. 15 is an experimental set-up of introducing more CH₃NH₂ gas into solution containing CH₃NH₂—PbI₂ and MAI;

FIG. 16 shows the device fabrication process stability (batch to batch variation with fresh ink);

FIG. 17 shows the ink shelf life (RT at ambient conditions) and effect on perovskite film quality;

FIG. 18 shows the effect of the ink aging to device performance;

FIG. 19 shows the perovskite film purity and homogeneity;

FIG. 20 shows solar cell performance stability (unencapsulated) with the top graph depicting the shelf stability at RT and 30% RH; and the lower graph depicting the thermal stability at 65° C. and 10% relative humidity (RH);

FIG. 21A shows a film produced with a solvent (ACN/MA) where MA denotes methylamine gas of the disclosed method and fabricated with one-step, antisolvent-free process;

FIG. 21B shows a film produced with a solvent (dimethylformamide (DMF)) of a conventional method and fabricated with one-step, antisolvent-free process;

FIG. 21C shows the PL lifetime indicating the defect density (comparison of films and devices);

FIG. 21D shows an I-V curve of the films produced in FIG. 21A and FIG. 21B indicating the defect density (comparison of films and devices);

FIG. 21E shows a Table with the properties as obtained for the films produced in FIG. 21A and FIG. 21B indicating the defect density (comparison of films and devices);

FIG. 22A shows the deposition of the perovskite ink as a perovskite film without the need for heating the perovskite film since a low boiling point solvent is used;

FIG. 22B shows a Table of how hazardous a selection of solvent is and shows that switching from DMF to acetonitrile represents a move towards benign solvents, the boiling points of some selected solvents are DMF=153° C., N-Methyl-2-pyrrolidone (NMP)=202° C., ACN=82° C., CH₃NH₂=−6° C., showing that it also represents moving towards low boiling point solvents, which allows less energy-intensive processing;

FIG. 23A shows a conventional process for perovskite formation;

FIG. 23B shows an annealing-free perovskite formation;

FIG. 24 shows the unoptimized RT-printed, annealing-free mini module;

FIG. 25A is a photograph of slot die coated perovskite film on 10×10 cm² substrates;

FIG. 25B shows the UV-vis absorbance of eight samples obtained from dividing big area slot die coated film;

FIG. 25C shows the GAXRD of eight samples obtained from dividing big area slot die coated film;

FIG. 26A is an illustration of a typical wet film of MAPbI₃ obtained from perovskite precursor ink composed of DMF as the solvent upon slot die coating at ambient condition;

FIG. 26B is an illustration of corresponding slot die coated MAPbI₃ film upon annealing;

FIG. 27A shows the statistical representations of 25 devices for open-circuit voltage (Voc);

FIG. 27B shows the statistical representations of 25 devices for short-circuit current density (J_{SC});

FIG. 27C shows the statistical representations of 25 devices for fill-factor (FF);

FIG. 27D shows the statistical representations of 25 devices for power conversion efficiency (η); and

FIG. 28 shows the ²⁰⁷Pb solid-state NMR spectra of [Pb(CH₃NH₂)I₂]ₙ under different MAS frequencies at RT.

### DETAILED DESCRIPTION

The following detailed description refers to the accompanying drawings that show, by way of illustration, specific details and embodiments in which the disclosure may be practiced. These embodiments are described in sufficient detail to enable those skilled in the art to practice the disclosure. Other embodiments may be utilized and structural, and logical changes may be made without departing from the scope of the disclosure. The various embodiments are not necessarily mutually exclusive, as some embodiments can be combined with one or more other embodiments to form new embodiments.

In a first aspect, the present disclosure refers to an organic metal-halide perovskite precursor including a divalent metal cation, a halide anion, and an alkylamine, wherein the divalent metal cation is connected to a nitrogen atom of the alkylamine via a covalent bond.

Advantageously, the organic metal-halide perovskite precursor of the present disclosure allows for a perovskite production that does not require the use of strongly coordinating, high boiling point solvents such as DMF and NMP which has been a major barrier to large scale manufacturing owing to the solvent handling and toxicology issues associated with them (the use of solvents like DMF and NMP in conventional perovskite film fabrication also typically requires additional “anti-solvent” such as chlorobenzene and diethylether to assist perovskite crystallization due to the high boiling point and coordination capability of DMF and NMP). All conventional approaches have been relying on metal halides MX₂ (e.g. PbI₂, SnI₂, and GeI₂) as the perovskite precursor material. However, as such metal halides are sparingly or completely insoluble in weakly-coordinating solvents, it was so far not possible to use “non-coordinating solvents” in perovskite fabrication. This has been made possible with the organic metal-halide perovskite precursor of the present disclosure, which is soluble in non-coordinating solvents. Advantageously, such a non-coordinating solvent may have a lower boiling point and a lower toxicity and may be more environmentally-friendly than conventional solvents used in perovskite synthesis. Manufacture of perovskites in a large scale is therefore facilitated.

The advantage of being able to use a non-coordinating solvent is believed to be attributed to the alkylamine being connected to the divalent metal cation via a covalent bond through the nitrogen atom. Since the alkylamine is part of the organic metal-halide perovskite precursor in the present disclosure, the incorporation of the alkylamine into the structure of the divalent metal cation and the halide anion through formation of a covalent bond leads to “trapping” of this gas molecule in the lattice. This “trapping” allows for a non-coordinating solvent to be used in the subsequent perovskite production method, since the alkylamine trapped in the structure of the divalent metal cation and the halide anion increases the solubility in a non-coordinating solvent.

The term “covalent bond”, as used herein, refers to the nitrogen atom of the amine functionality that is part of the alkylamine, sharing its valence electrons with the divalent metal cation. The covalent bond is contrasted herein with an ionic attraction, which is typically encountered in salts. The covalent bond may further be described as a coordinate covalent bond, or dative bond, dipolar bond, or coordinate bond. It indicates that both electrons of the bond originate from the nitrogen atom of the alkylamine. The alkylamine could therefore be termed as a “ligand”.

The term “divalent metal cation”, as used herein, refers to any metal cation which may form a perovskite and is present in the oxidation state +II. Notably, the divalent metal of the divalent metal cation may be selected from the group consisting of transition metals, lanthanoids, post-transition metals and heavy metals. In some embodiments, the metal cation is any metal of group 11, group 14 or group 15 of the periodic system or a mixture of these. Consequently, the divalent metal cation may be selected from the group consisting of copper, silver, gold, germanium, tin, lead, arsenic, antimony, bismuth, and a combination thereof. In some embodiments, the divalent metal cation may be a heavy metal cation. In some embodiments, the divalent metal cation may be a mixture of several heavy metal cations. Heavy metals may be associated with a higher density and a lower reactivity than other (light) metals. As such, the divalent heavy metal may be selected from zinc, mercury, lead, iron, copper, tin, silver, gold, platinum, gallium, thallium, hafnium, cobalt, ruthenium and indium. In one example, the heavy metal cation is lead.

Additionally or alternatively, the divalent metal cation may be a post-transition metal. Post-transition metals may refer to the metallic elements in the periodic table located between the transition metals (to their left) and the metalloids (to their right). These elements may include gallium, indium thallium, tin, lead, bismuth, cadmium, mercury and aluminum. In one example, the post-transition metal cation is lead.

The term “alkylamine”, as used herein, refers to an organic compound that includes at least one nitrogen atom that is covalently bonded to a carbon atom that is sp³-hybridized. Optionally, the alkylamine is selected from a low molecular weight compound, such that it is volatile under ambient conditions. It may thus be an amine-based gas. An amine-based gas may be used to enhance the quality of the perovskite layers being fabricated. The amine may be a primary amine or a secondary amine. Depending on the type of amine, the alkyl may include one, two, or three moieties. Suitable alkyl moieties may be organic moieties as further defined below.

Surprisingly, by employing an alkyl that is sp³-hybridized, the alkyl may be able to provide a positive inductive (+I) effect on the nitrogen atom, thereby increasing its nucleophilicity and enhancing the strength of the covalent bond.

The halide anion may be an iodide, a bromide, a chloride or a mixture thereof. Halide anions may be monovalent anions. In one example, the halide anion is an iodide.

According to various embodiments, the organic metal-halide perovskite precursor is thermally stable up to a temperature of at least 50° C., or up to a temperature of at least 60° C., or up to a temperature of at least 70° C., or of at least 90° C. “Thermally stable”, as used herein, means that no, or substantially no gas is released from the organic metal-halide perovskite precursor up to the stated temperature. This high thermal stability is evidence to a strong covalent bond between the nitrogen and the divalent metal.

According to various embodiments, the covalent bond may have a length of less than 4 angstrom (Å), or less than 3 Å, or less than 2.5 Å. This low bond length may be further evidence to the covalent nature of the nitrogen-lead bond.

According to various embodiments, the organic metal-halide perovskite precursor may be of the general structure: RNH₂-MX₂(Formula (I)). In this general structure it is understood that the nitrogen N is bonded to the metal M. According to these embodiments, the amine in the alkylamine may be a primary amine. Advantageously, when a primary amine is used, the nucleophilicity of the amine is sufficiently high to engage into covalent bonding with the divalent metal cation. The nitrogen of the amine may be bonded to a single organic moiety.

In Formula (I), R may be an organic moiety. The term “organic moiety” as used herein refers to carbon-containing moieties. These moieties can be linear or branched, substituted or unsubstituted, and are derived from hydrocarbons, typically by substitution of one or more carbon atoms by other atoms, such as oxygen, nitrogen, sulfur, phosphorous, or functional groups that contain oxygen, nitrogen, sulfur, phosphorous. The organic moiety can comprise any number of carbon atoms, but has preferably a molecular weight of below 100 g/mol or below 80 g/mol.

In a preferred embodiment, the organic moiety can be a linear or branched, substituted or unsubstituted alkyl with 1 to 10 carbon atoms; linear or branched, substituted or unsubstituted alkenyl with 2 to 10 carbon atoms; linear or branched, substituted or unsubstituted alkynyl with 2 to 10 carbon atoms; linear or branched, substituted or unsubstituted alkoxy with 1 to 10 carbon atoms; substituted or unsubstituted cycloalkyl with 3 to 10 carbon atoms; substituted or unsubstituted cycloalkenyl with 3 to 10 carbon atoms; substituted or unsubstituted aryl with 6 to 10 carbon atoms; and substituted or unsubstituted heteroaryl with 3 to 9 carbon atoms.

The organic moiety can also be a combination of any of the above-defined groups, including but not limited to alkylaryl, arylalkyl, alkyl heteroaryl and the like, to name only a few, all of which may be substituted or unsubstituted.

The term “substituted” as used herein in relation to the above moieties refers to a substituent other than hydrogen. Such a substituent is preferably selected from the group consisting of halogen, —OH, —OOH, —NH₂, —NO₂, —ONO₂, —CHO, —CN, —CNOH, —COOH, —SH, —OSH, —CSSH, —SCN, —SO₂OH, —CONH₂, —NH—NH₂, —NC, —CSH—OR, —NRR′, —NR, —C(O)R, —C(O)OR, —(CO)NRR′, —NR′C(O)R, —OC(O)R, aryl with 5 to 10 carbon atoms, cycloalk(en)yl with 3 to 10 carbon atoms, 3- to 8-membered heterocycloalk(en)yl, and 5- to 10-membered heteroaryl, wherein R and R′ are independently selected from hydrogen, alkyl with 1 to 10 carbon atoms, alkenyl with 2 to 10 carbon atoms, alkynyl with 2 to 10 carbon atoms, aryl with 5 to 10 carbon atoms, cycloalk(en)yl with 3 to 10 carbon atoms, 5- to 10-membered heteroaryl, comprising 1 to 4 heteroatoms selected from nitrogen, oxygen, and sulfur, and 5- to 10-membered heterocycloalk(en)yl, comprising 1 to 4 heteroatoms selected from nitrogen, oxygen, and sulfur. Any of these substituents may again be substituted, it is however preferred that these substituents are unsubstituted.

Cycloalkyl refers to a non-aromatic carbocyclic moiety, such as cyclopentanyl, cyclohexanyl, and the like.

Cycloalkenyl refers to non-aromatic carbocyclic compounds that comprise at least one C—C double bond.

Similarly, heterocycloalk(en)yl relates to cycloalk(en)yl groups wherein 1 or more ring carbon atoms are replaced by heteroatoms, preferably selected from nitrogen, oxygen, and sulfur.

Aryl relates to an aromatic ring that is preferably monocyclic. Preferred aryl substituents are moieties with 6 carbon atoms, such as phenyl.

Heteroaryl refers to aromatic moieties that correspond to the respective aryl moiety wherein one or more ring carbon atoms have been replaced by heteroatoms, such as nitrogen, oxygen, and sulfur.

All of the afore-mentioned groups can be substituted or unsubstituted. When substituted, the substituent can be selected from the above list of substituents.

The term ‘at least one’ as used herein relates to one or more, for example 1, 2, 3, 4, 5, 6, 7, 8, 9 or more of the referenced species.

In Formula (I), M may be the divalent metal cation as described herein before.

In Formula (I), X may be the halide anion as described herein before.

In Formula (I), R may be a linear or branched, substituted or unsubstituted C₁-C₁₀ alkyl; linear or branched, substituted or unsubstituted C₂-C₁₀ alkenyl; linear or branched, substituted or unsubstituted C₂-C₁₀ alkynyl; linear or branched, substituted or unsubstituted C₁-C₁₀ alkoxy; substituted or unsubstituted C₃-C₁₀ cycloalkyl; substituted or unsubstituted C₃-C₁₀ cycloalkenyl; substituted or unsubstituted C₆-C₁₀ aryl; substituted or unsubstituted C₃-C₁₀ heteroaryl. For example, R may be a linear or branched, substituted or unsubstituted C₁-C₈ alkyl, or a linear or branched, substituted or unsubstituted C₁-C₆ alkyl, or a linear or branched, substituted or unsubstituted C₁-C₄ alkyl, or a linear or branched, substituted or unsubstituted C₁-C₂ alkyl.

In some embodiments, the organic moiety may be at least one alkyl moiety. The alkyl moiety may be branched or linear. In some embodiments, the at least one alkyl moiety may be at least one linear alkyl moiety. In some embodiments, the organic moiety may be a methyl moiety (—CH₃). Together with the amine, the RNH₂ may be methylamine (CH₃NH₂). Advantageously, when using methylamine as the alkylamine, the quality of the ensuing perovskite structures may be very high.

In Formula (I), X may be a halide, such as bromide or iodide.

M may be any divalent metal cation of group 14. The divalent metal cation of group 14 may be a lead cation or a tin cation. Advantageously, when the divalent metal cation is a lead cation or a tin cation, the efficiency of the of the resulting perovskite solar cells is enhanced.

According to various embodiments, the organic metal-halide perovskite precursor may be a crystalline solid. Moreover, the organic metal-halide perovskite precursor may be present in the form of polymeric layers. The polymeric layers may be essentially two-dimensional (2D) “corrugated” polymeric layers that comprise M(alkylamine)X₂ monomers. The divalent metal cations therein may be five coordinate and the resulting square pyramids may be connected to one another via the bridging halide anions in edge- and vertex-sharing fashion. Accordingly, the divalent metal cation may have a five-coordinate metal center in a square pyramid coordination.

In a second aspect, there is provided a process for the production of an organic metal-halide perovskite precursor comprising a divalent metal cation, a halide anion and an alkylamine, wherein a covalent bond connects the divalent metal cation to a nitrogen atom of the alkylamine, the process including: a) forming a solution comprising an organic solvent system and following reagents dissolved therein: a first salt of the divalent metal cation with the halide anion; a second salt of an alkylammonium cation with the halide anion; and the alkylamine; and b) crystallizing the organic metal-halide perovskite precursor from the solution.

With regard to the first salt, the divalent metal cation may be selected from the same divalent metal cation as described for the first aspect. The halide anion may be selected from the same halide anion as described for the first aspect. Accordingly, in some embodiments, the first salt may be MX₂. In one example, the first salt may be PbI₂.

With regard to the second salt, the alkyl of the alkylammonium cation may be selected from the same alkyl as the alkyl used in the alkylamine. The halide anion may be selected from the same halide anion as the halide anion used in the first aspect. In some embodiments, the second salt may be alkylammonium halide. In one example, the second salt may be MAI.

Advantageously, the process may be easily upscaled. For example, it is possible to produce several kg of the organic metal-halide perovskite precursor by this procedure.

The process step a) may be carried out under the exclusion of water and/or oxygen.

According to various embodiments, step a) may further include preparing a precursor solution from the first salt and the second salt, both dissolved in a first organic solvent. The solvent for dissolving the first salt and the second salt may be a first organic solvent, e.g. ethyl acetate. The first and the second salt may be added in stoichiometric amounts to each other. Hence, the ratio may be about 0.6:1 to about 1.4:1, optionally about 0.8:1 to about 1.2:1, or about 1:1.

According to various embodiments, step a) may further include adding the alkylamine dissolved in a second organic solvent (e.g. ethanol) to the precursor solution. The alkylamine may be the same as described for the first aspect.

Both the first and the second solvent may be non-coordinating organic solvents, optionally and independently selected from the group consisting of tetrahydrofuran, ethyl acetate, acetone, acetonitrile, alcohols (such as methanol, ethanol or isopropanol), and mixtures thereof.

Step a) of the process may further include stirring the precursor solution at room temperature. “Room temperature”, as used herein, refers to a temperature greater than 4° C., preferably from 15° C. to 40° C., 15° C. to 30° C., and 15° C. to 24° C., and 16° C. to 21° C. Such temperatures may include, 14° C., 15° C., 16° C., 17° C., 18° C., 19° C., 20° C., and 21° C.

According to various embodiments, step b) may include the crystallization to be carried out substantially disturbance-free. “Substantially disturbance-free” may mean that the solution is not stirred or shaken for a predetermined time lasting generally more than one hour.

According to various embodiments, the solution may have a concentration of the divalent metal cation of at least 0.4 M. Advantageously, the concentration of the divalent metal cation of at least 0.4 M allows for the organic metal-halide perovskite precursor to crystallize from solution at room temperature.

By crystallizing the organic metal-halide perovskite precursor from the solution, a high purity of single crystals of the organic metal-halide perovskite precursor may be obtained. Advantageously, the high purity of the single crystals in the subsequent perovskite ink and the ability of the alkylamine to reduce sources of defects such as halogens or polyhalide species in solution allow the formation of high quality perovskite films from the single crystals.

According to various embodiments, step b) may further include separating the organic metal-halide perovskite precursor from the solution. This separation may be a filtration and/or decantation. After the separation, the organic metal-halide perovskite precursor may be dried.

In a third aspect, there is provided a perovskite ink including the organic metal-halide perovskite precursor as described in the first aspect and a non-coordinating solvent, wherein the organic metal-halide perovskite precursor is dissolved in the non-coordinating solvent. The non-coordinating solvent may be an organic solvent. Advantageously, the non-coordinating solvent is environmentally-friendly, has a low toxicity (or substantially no toxicity) and has a low boiling point. The purity of the organic metal-halide perovskite precursor single crystals in the perovskite ink and the ability of the alkylamine to reduce sources of defects such as halogens or polyhalide species in solution allow the formation of high quality perovskite films from the perovskite ink. This eventually results in efficient and stable perovskite devices, fabricated via single step anti-solvent-free deposition method, which is, for example, technically transferable to large-area slot die coating.

According to various embodiments, the non-coordinating solvent may be selected from the group consisting of acetonitrile, tetrahydrofuran, acetone, ethyl acetate, alcohol, and a combination thereof.

According to various embodiments, the perovskite ink may further include an additional amount of the second salt as described above. A further additive may be added which includes an alkylammonium thiocyanate. In one example, the additive may be MA(SCN), optionally in an amount of less than 10 mol % (relative to the divalent metal cation). Upon mixing the organic metal-halide perovskite precursor in the non-coordinating solvent with the second salt, the alkylamine may be liberated into the ink solution (i.e., no longer coordinated to the M²⁺ metal cation, which allows the metal halide polymer to dissociate into the halometallate species in solution), thereby further increasing solubility of the divalent metal cation in the non-coordinating solvent for further processing.

Accordingly, after mixing the organic metal-halide perovskite precursor in the non-coordinating solvent with the second salt, a perovskite solution may be obtained, which in overall, comprises the divalent metal cation, the halide anion, and the alkylamine, dissolved in the non-coordinating solvent. In this embodiment, the alkylamine is liberated from the organic metal-halide perovskite precursor to give the perovskite solution. In this embodiment, the divalent metal cation may be associated with the nitrogen atom of the alkylamine non-covalently.

The ratio of the organic metal-halide perovskite precursor to the second salt in the perovskite ink may be about 0.6:1 to about 1.4:1, optionally about 0.8:1 to about 1.2:1, optionally about 1:1. The perovskite ink may have a concentration of the divalent metal cation of at least 0.4 M. Moreover, during preparation of the perovskite ink, an additional amount of the alkylamine may be added to the perovskite ink.

In a fourth aspect, there is provided a perovskite including a divalent metal cation, a halide anion, and an alkylamine, prepared from a perovskite ink or a perovskite solution as described above.

The perovskite ink or the perovskite solution may be deposited on a substrate. The substrate may be a hydrophilic substrate. The substrate may be selected from the group consisting of glass, quartz, polyethylene terephthalate (PET), polyethylene naphthalate (PEN), silicon dioxide etc. The substrate may be coated with indium tin oxide (ITO), fluorine-doped tin oxide (FTO) or any other conducting layer. The substrate may further comprise an electrode. In some embodiments, ITO may be the electrode.

Depositing the perovskite ink or the perovskite solution on the substrate may proceed by any methodology. For example, the deposition may be carried out by slot die coating, spin coating, doctor blading or inkjet printing. Advantageously, the deposition may be carried out at room temperature. The deposition may further comprise the production of the perovskite as discussed above.

The perovskite may be present as a film on the substrate. Hence, there is provided a perovskite film on a substrate. The perovskite film may be polycrystalline. Additionally or alternatively, the perovskite film may have a film thickness of about 10 nm to about 1000 nm, or about 100 nm to about 500 nm, or about 200 nm to about 400 nm. The above-mentioned range may be suitable for the applications of the perovskite in solar cells, light emitting diodes etc.

Features that are described in the context of an embodiment may correspondingly be applicable to the same or similar features in the other embodiments. Features that are described in the context of an embodiment may correspondingly be applicable to the other embodiments, even if not explicitly described in these other embodiments. Furthermore, additions and/or combinations and/or alternatives as described for a feature in the context of an embodiment may correspondingly be applicable to the same or similar feature in the other embodiments.

In the context of various embodiments, the articles “a”, “an” and “the” as used with regard to a feature or element include a reference to one or more of the features or elements.

As used herein, the term “and/or” includes any and all combinations of one or more of the associated listed items.

### Examples

In order to overcome the shortcomings in traditional perovskite manufacturing, the disclosure utilizes the coordination chemistry of the RNH₂ gas itself where R corresponds to organic functional groups (e.g. alkyls, phenyls, and carboxamidines). In principle, due to the basicity of the amine group, it is feasible for RNH₂ molecule to bind (i.e. form covalent bond as opposed to weak intermolecular interaction) to Lewis-acidic M²⁺ metal center, leading to a possible formation of a new class of compound. Indeed, this is what has been observed in other systems:

hybrid polymeric adducts of MX₂ with coordinating solvents DMF and DMSO (dimethylsulfoxide) have been isolated and identified as key intermediates of the perovskite crystallization. As such, we postulate that the incorporation of RNH₂ into the MX₂ structure through formation of covalent bond should be achievable under certain condition, leading to “trapping” of this gas molecule in the halometallate lattice. Following that, we attempted to prepare such organic metal halide coordination polymers RNH₂-MX₂, to be used as a precursor to perovskite ink solution. Herein, CH₃NH₂—PbI₂ is chosen as a prototypical compound. It could be obtained by preparing concentrated solution of PbI₂ and MAI in a mixture of CH₃NH₂, ethanol, and ethyl acetate under inert condition, initiating the reaction between CH₃NH₂ and [PbI₆]⁴⁻. Leaving the solutions standing for at least 24 h, free from disturbances, eventually resulted in big yellow colored single crystals of reasonable yield (over 70% relative to Pb²⁺).

### Technical Description of the Disclosure

Structural and Spectroscopic Properties

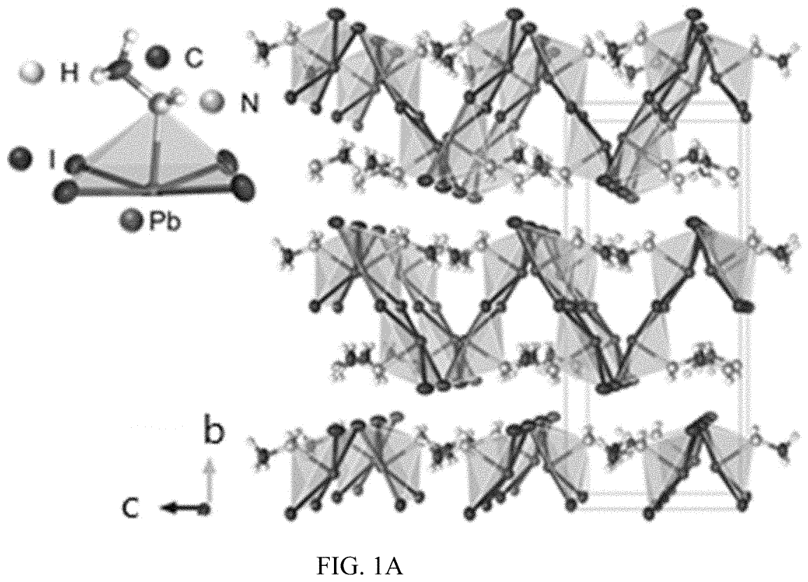

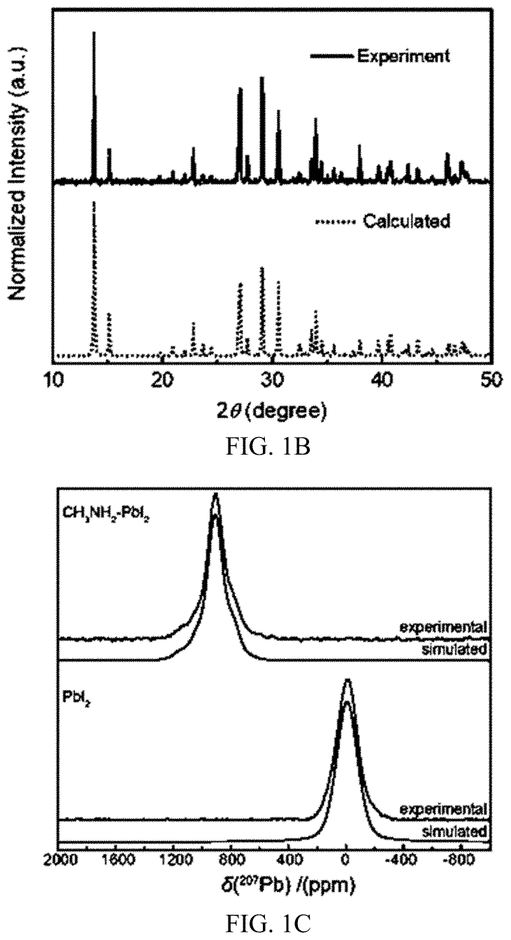

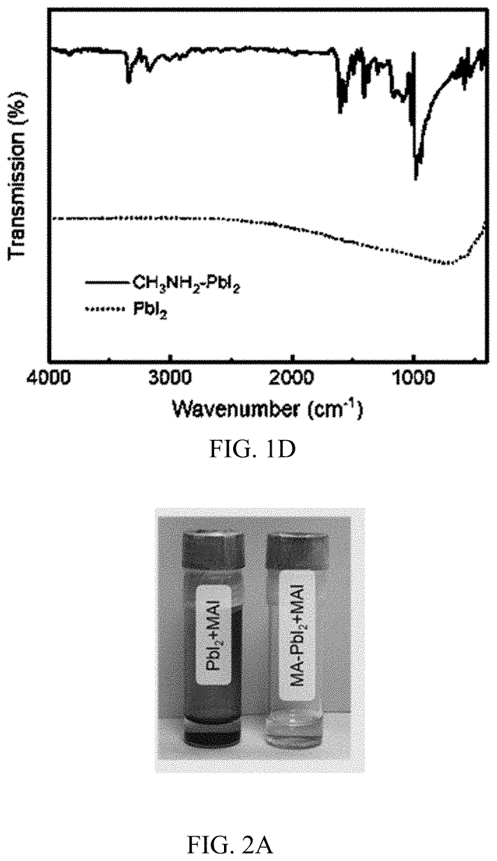

X-ray crystallographic analysis of the compound formed, CH₃NH₂—PbI₂, yielded a well-defined structure displayed in FIG. 1A. The compound features two-dimensional (2D) “corrugated” polymeric layers that comprises Pb(CH₃NH₂)I₂ monomers. The Pb²⁺ ions therein are five coordinate and the resulting square pyramids connect to one another via the bridging I⁻ ions in edge- and vertex-sharing fashions. Such coordination geometry exhibited by Pb²⁺ in CH₃NH₂—PbI₂ is very rare and there appears to be only 1 precedent report of hybrid lead iodide-based coordination polymer exhibiting similar geometry (out of the more than 60 examples reported in the Cambridge Structural Database). The more common six coordinate are found, for example, in coordination complexes of iodoplumbates with DMF, DMSO, or pyridines.

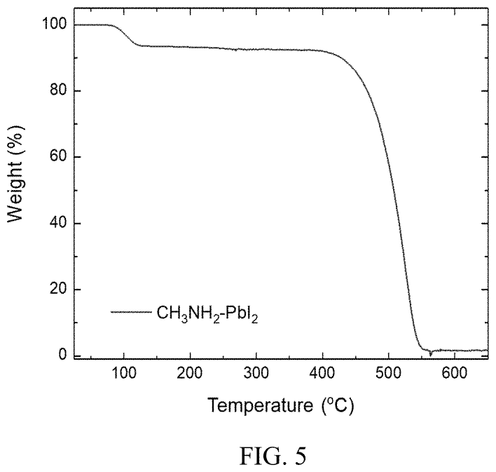

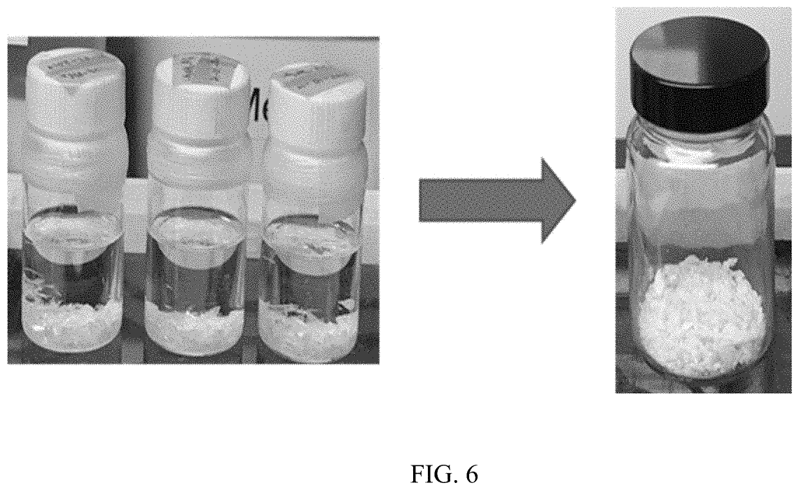

The disclosed compound also represents the first example of organoiodoplumbate coordination polymer where monoamine is used as the organic ligand. CH₃NH₂ coordinates strongly to the metal center with Pb—N bond distance being 2.452 Å. Such strong coordination of the amine functionality is accentuated by the thermal stability of the complex. As shown in thermal gravimetric analysis (TGA) plot of CH₃NH₂—PbI₂, degradation corresponding to the release of CH₃NH₂ gas does not occur up to 100° C. (FIG. 5). The CH₃NH₂—PbI₂ single crystals can be obtained in high purity and most importantly, it can be isolated in a big amount as a bulk. FIG. 6 shows around 25 g of isolated CH₃NH₂—PbI₂. The purity of resulting bulk is further confirmed using PXRD carried out under inert condition. As shown in FIG. 1B, the PXRD pattern of synthesized crystalline CH₃NH₂—PbI₂ is well in agreement with the material's simulated RT PXRD pattern.

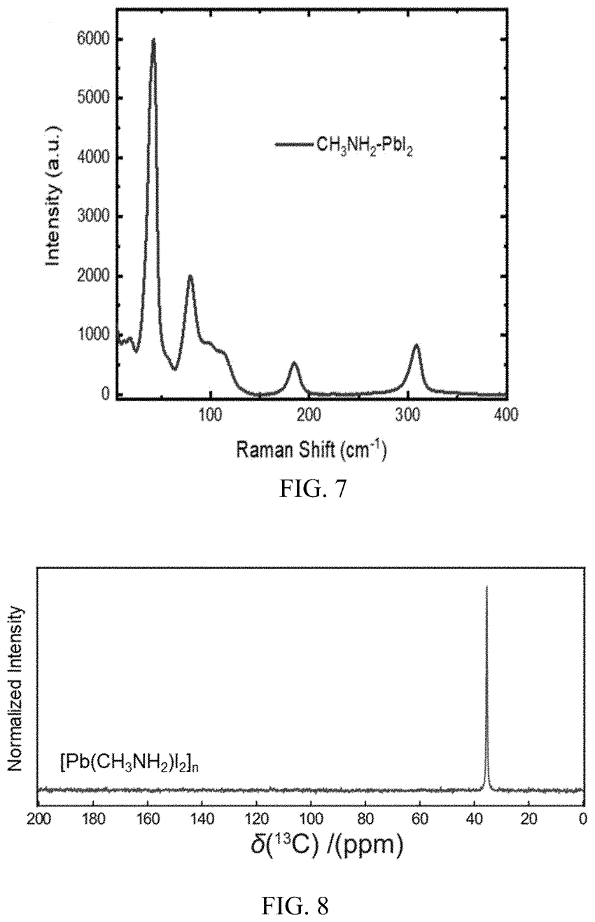

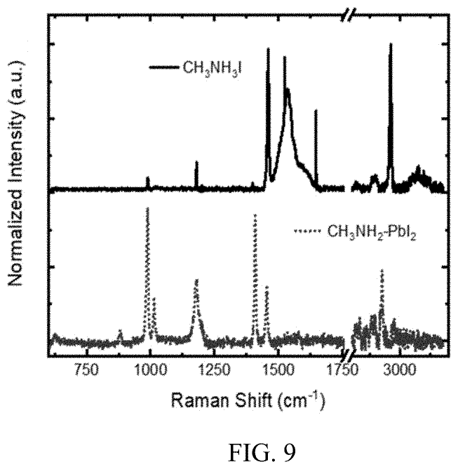

Several spectroscopic characterizations of this new hybrid compound were then carried out to further probe its unique structural features. As a result of its 2D inorganic lattice, sharp and narrow peaks, typical of rigid Pb—I lattices stretching in the low-dimensional structures, can be observed in the low frequency region of the Raman spectrum (FIG. 7) of CH₃NH₂—PbI₂. Interestingly, however, CH₃NH₂—PbI₂ exhibit spectroscopic features that are distinctive to those of the more commonly used perovskite precursor, PbI₂. For example, the differing coordination environments of Pb in CH₃NH₂—PbI₂ in comparison to PbI₂, can be discerned using SSNMR measurements (FIG. 1C). Particularly, the ²⁰⁷Pb SSNMR spectrum of CH₃NH₂—PbI₂ contains a single resonance at 905 ppm, whereas that of ²⁰⁷Pb in PbI₂ falls at −10 ppm. In addition, unlike PbI₂ which exhibits a Gaussian-shape resonance, asymmetry in its line-shape can be observed in that of CH₃NH₂—PbI₂ as a result of the reduced symmetry about its Pb atom coordination geometry, in comparison to the octahedral Pb—I configurations in PbI₂.

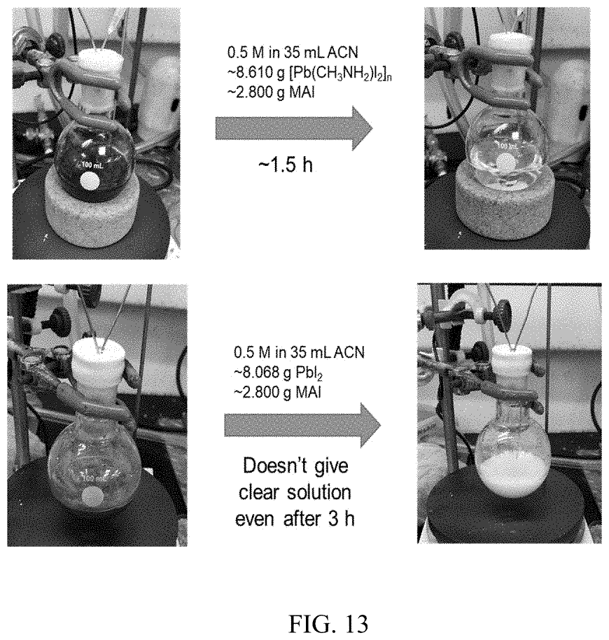

Due to the presence of CH₃NH₂, moreover, organic fingerprint can noticeably be observed in CH₃NH₂—PbI₂ from its FT-IR spectrum, a feature that is otherwise absent in PbI₂ (FIG. 1D). As the consequence of its binding with Pb²⁺, variation in the spectroscopic properties is also apparent with organic CH₃NH₂ in CH₃NH₂—PbI₂, when it is compared to the CH₃NH₃I (methylammonium iodide; MAI) counterpart. As can be seen in its ¹³C SSNMR spectrum, a single resonance, owing to the methyl functionality, at 35 ppm is yielded (FIG. 8). Such resonance has a distinct chemical environment in comparison to that in MAI where resonance at 29 ppm has been reported. The downfield shift suggests that, relative to ammonium group, the bonding with Pb⁺² by the N atom results in a more withdrawing environment for the C atom in CH₃ functionality. Additionally, high frequency Raman signature of CH₃NH₂ in CH₃NH₂—PbI₂ has also changed in comparison to MAI as a result of coordination to Pb²⁺, though an exact assignment would require combination of calculation and measurement at low temperature (FIG. 13).

Physicochemical Properties

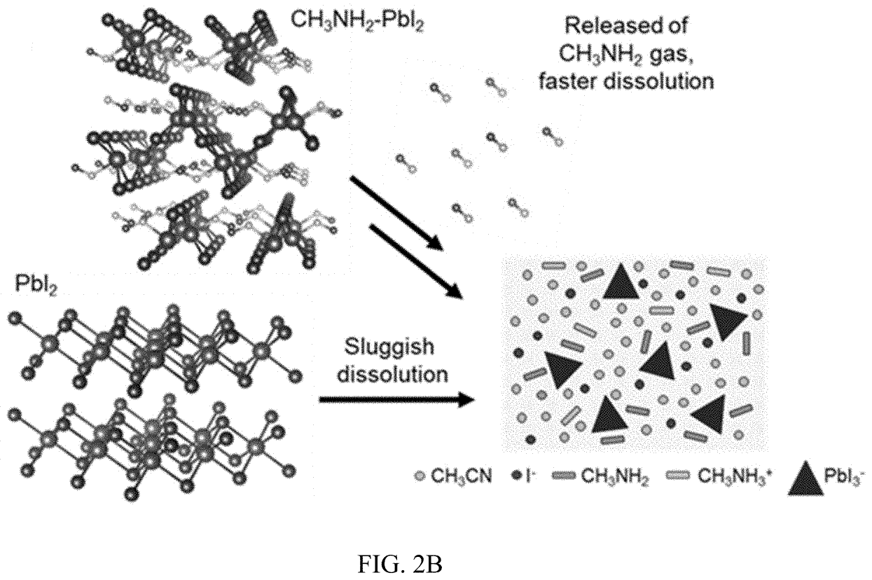

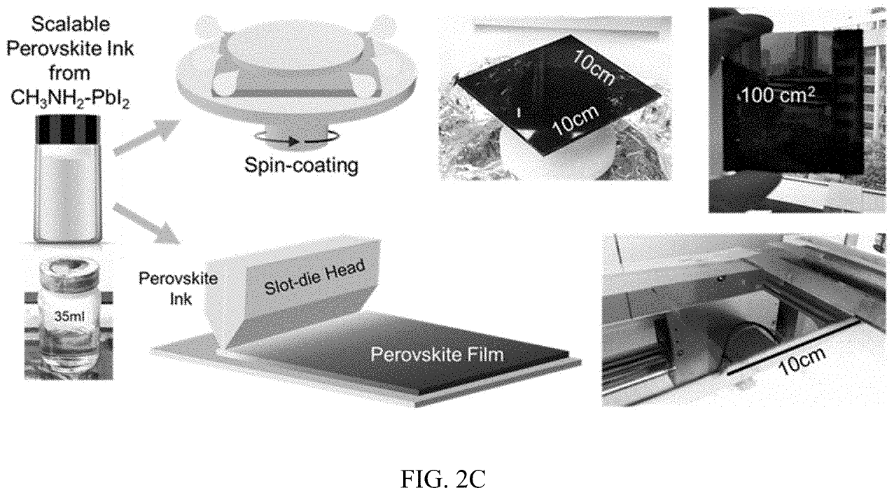

In order to exploit the “trapped” CH₃NH₂, CH₃NH₂—PbI₂ was utilized as the Pb′ source to fabricate perovskite with nonconventional processing, weakly coordinating solvent, such as ACN. Intriguingly, in comparison to conventional PbI₂, the presence of extra CH₃NH₂ gas molecule in CH₃NH₂—PbI₂ is found to increase the perovskite solubility. As shown in FIG. 2A, a clear solution could be obtained by mixing CH₃NH₂—PbI₂ and MAI in ACN in concentration of around 100 mM. On the other hand, black suspension was obtained with the same concentration when PbI₂ was used. As such, CH₃NH₂—PbI₂ can be seen as the “CH₃NH₂ gas carrier” that is capable of liberating CH₃NH₂ upon dissolution. Apart from its ability in enhancing perovskite solubility in nonconventional solvent, the addition of CH₃NH₂ molecule is also expected to reduce source of defects, such as iodine (I₂) and/or polyiodide species, as what has been demonstrated elsewhere.

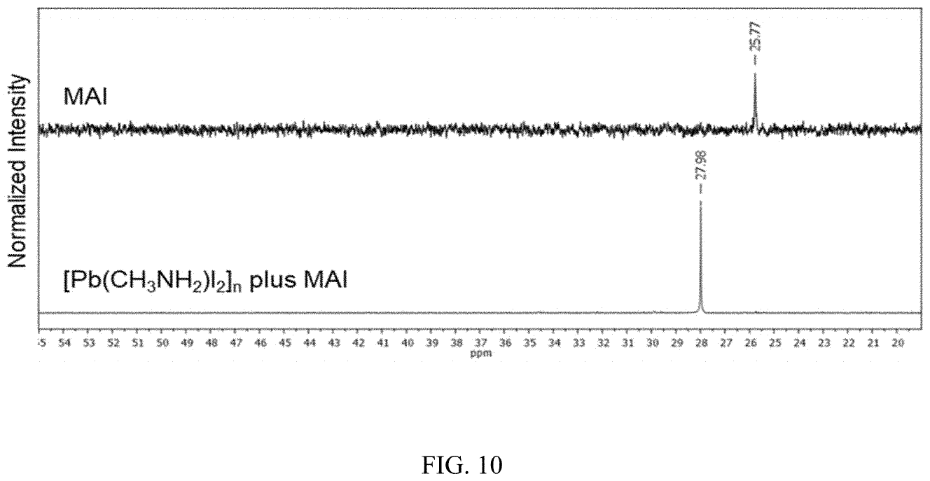

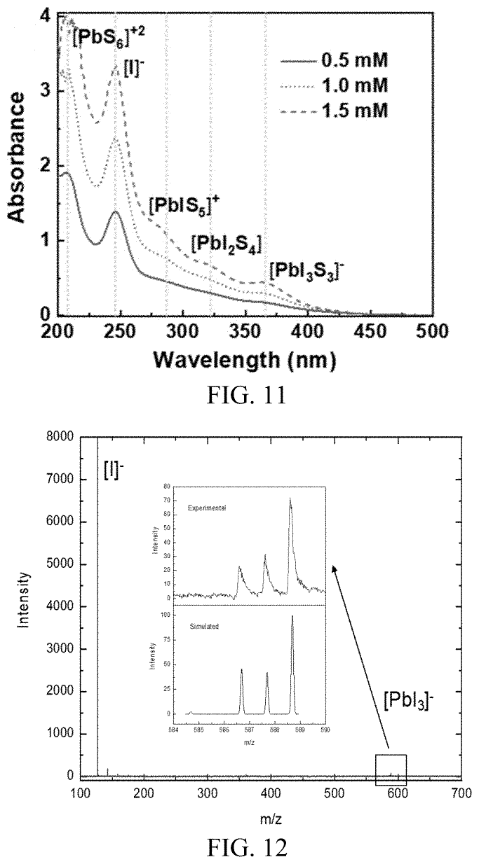

This observation resonates the precedent report: as evidenced from UV-vis spectra of different concentrations of CH₃NH₂—PbI₂ and MAI solution in ACN, the peak attributed to [PbI₃S₃]⁻, where S is coordinating solvent, (presumably CH₃NH₂ in this disclosure; see FIG. 10 for solution state NMR analysis of CH₃NH₂ binding), at ca. 370 nm appears in a very low intensity relative to the other peaks (FIG. 11). In addition, from the mass spectrometry spectrum, it was also found that the relative amount of [PbI₃]⁻ species (m/z=ca. 588.70) is much lower in comparison to that of I⁻ (m/z=ca. 126.89; see FIG. 12 for further discussion). The observed ability of CH₃NH₂ to suppress the iodine and/or polyiodide species in solution may promote formation of high quality perovskite film with reduced trap densities.

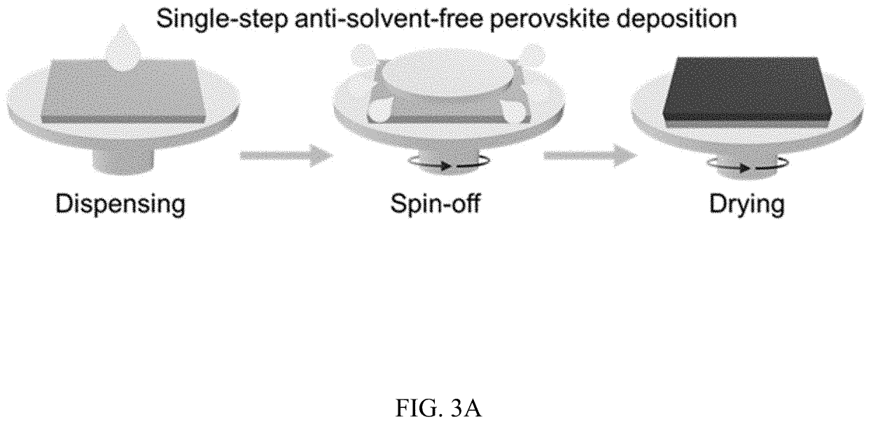

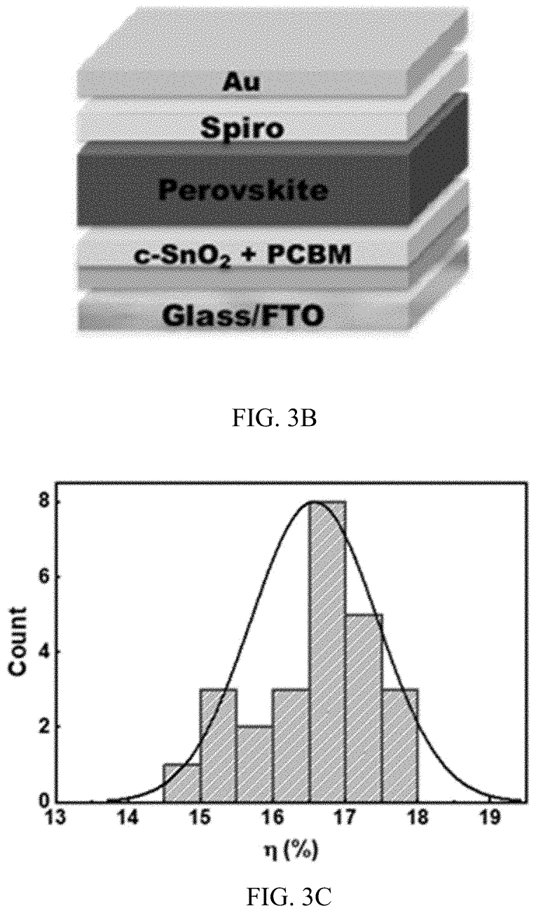

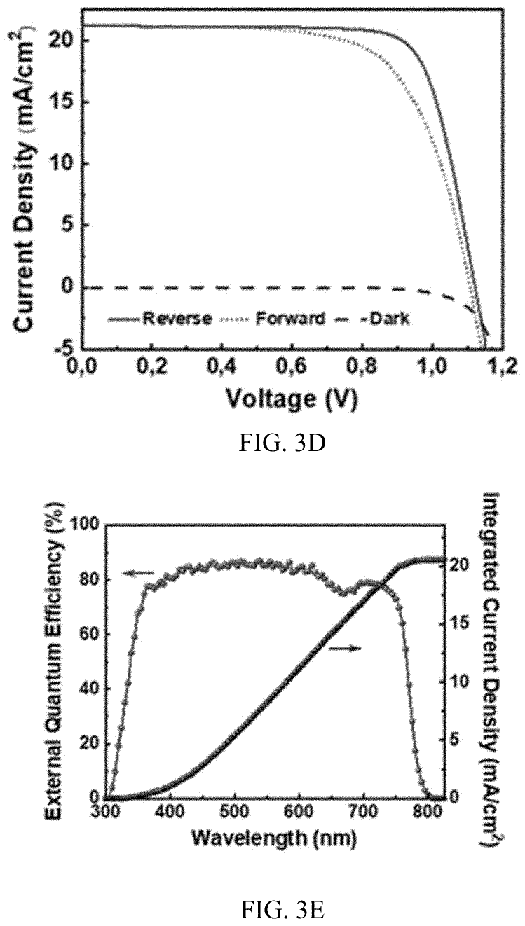

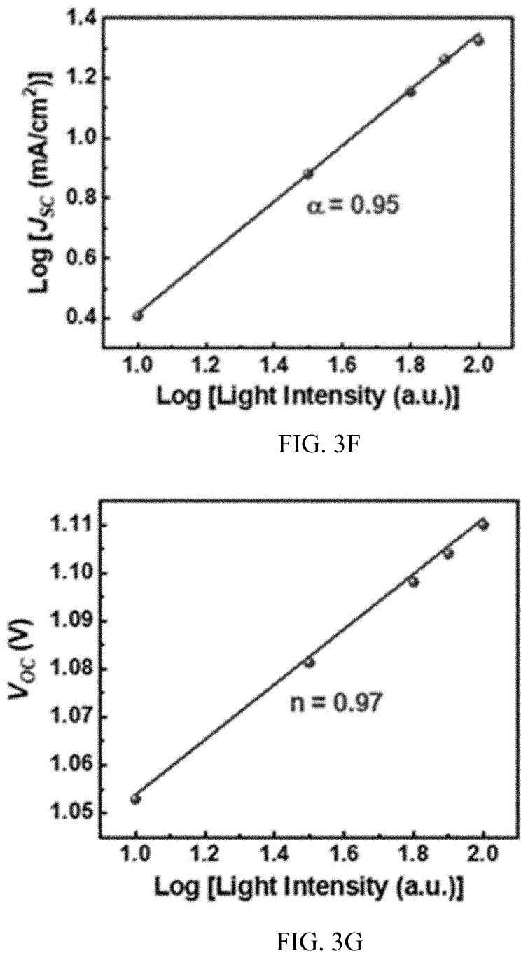

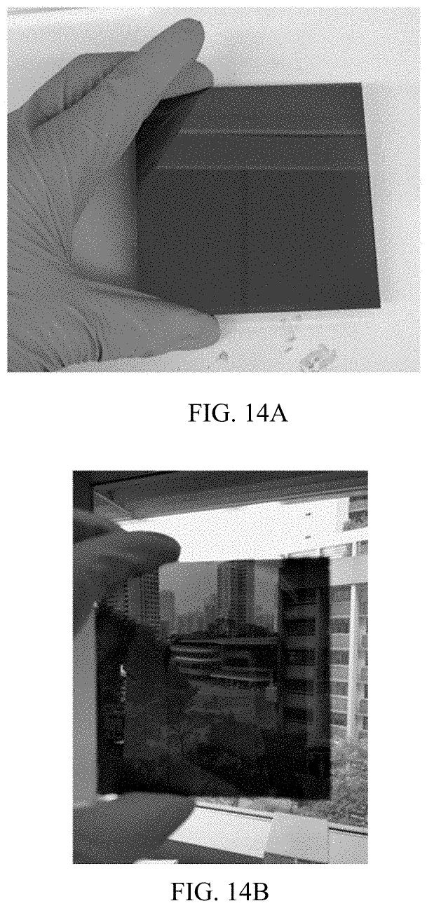

The CH₃NH₂—PbI₂ precursor was also found to be capable of improving the perovskite solubility when it was attempted to introduce more CH₃NH₂ gas into suspensions containing CH₃NH₂—PbI₂ and MAI with molar concentration higher than 100 mM. In particular, a much faster dissolution process was observed in comparison to when PbI₂ was used as a precursor. This observation became more apparent when higher concentration or huge amount of solution was used. For example, with the disclosed set-up, in order to dissolve 0.50 M of 35 mL of solution, typically 5 hours are required to get clear solution with PbI₂ and MAI starting precursors. Replacing PbI₂ with CH₃NH₂—PbI₂, by maintaining the flow and stirring rate for equal comparison, the dissolution time was reduced to around 1.5 hours (FIG. 13). This, as mentioned previously, can be attributed to the extra CH₃NH₂ molecule that is “carried” by the compound (FIG. 2B). The ability of the disclosed compound to provide faster solubilization of perovskite eventually allowed to prepare sufficient amount of ink needed for fabrication of large perovskite films, such as via spin coating and slot die coating processes (FIG. 2C). Coupled with the fast evaporation of the solvent, perovskite films featuring fully covered, pin-holes-free, uniform morphology can be obtained on large area substrate at room temperature without the need of anti-solvent (FIG. 2C, FIG. 3A and FIG. 14). Thus, a potential use of the disclosed compound for the scale-up of the perovskite ink when the required amount of ink is huge is expected.

Advantages and Improvements Over Existing Methods, Devices or Materials

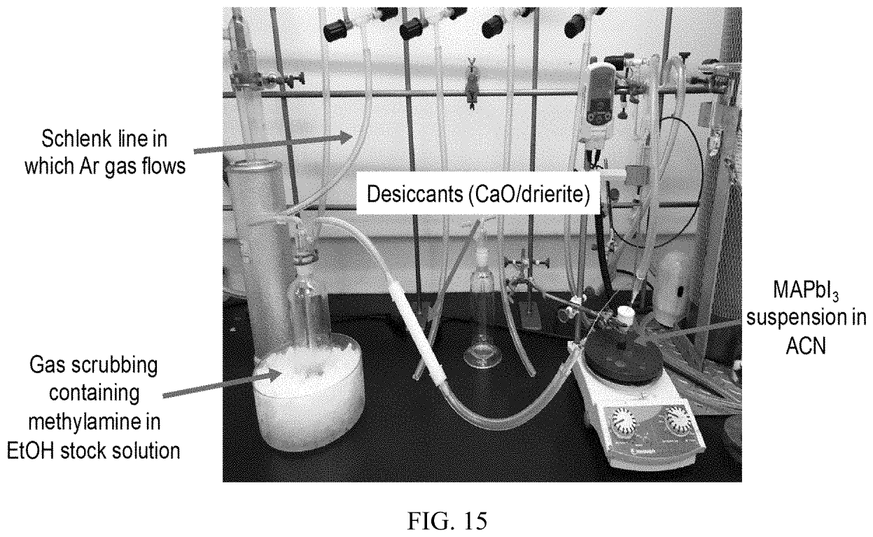

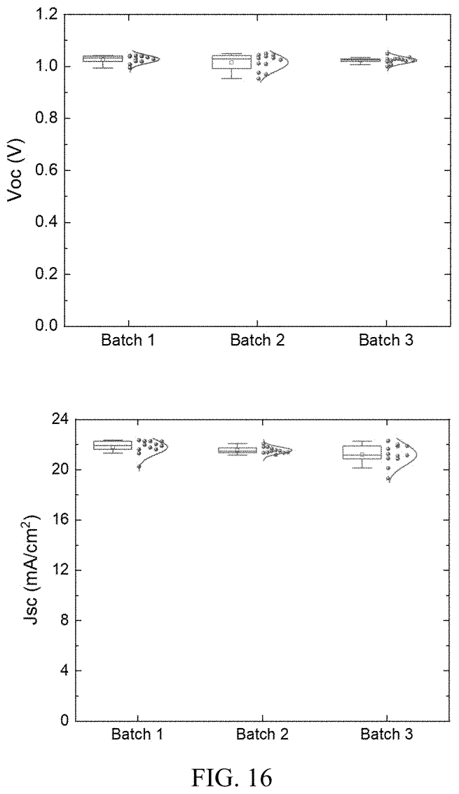

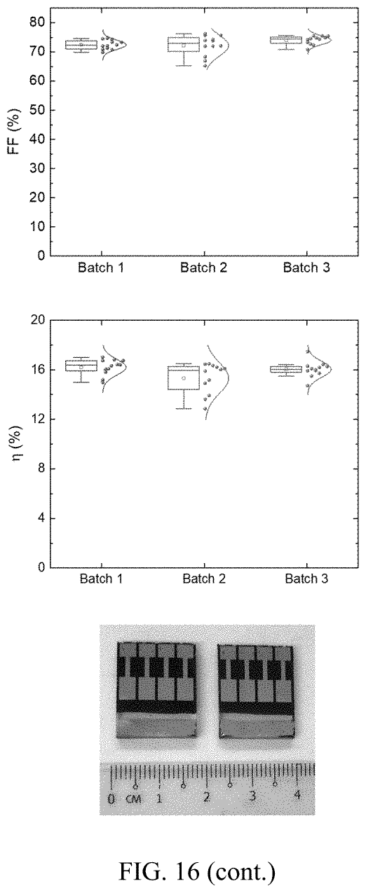

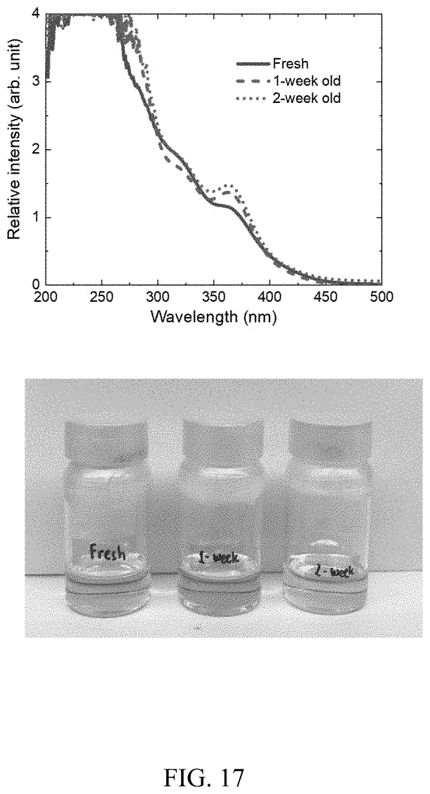

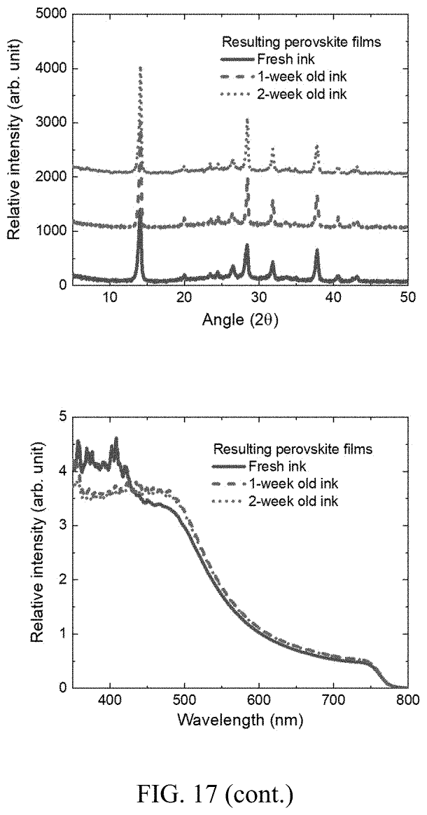

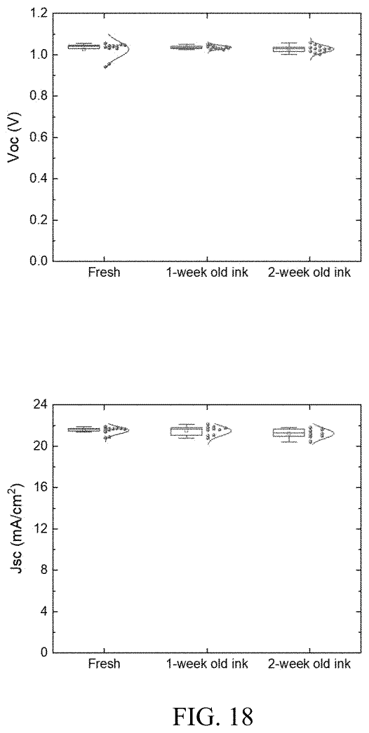

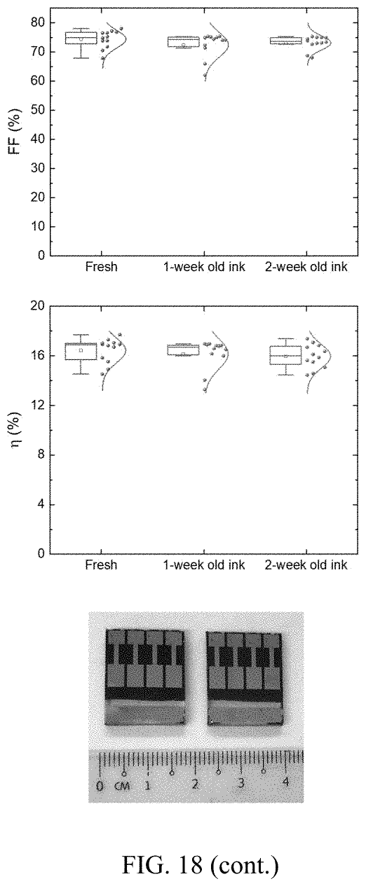

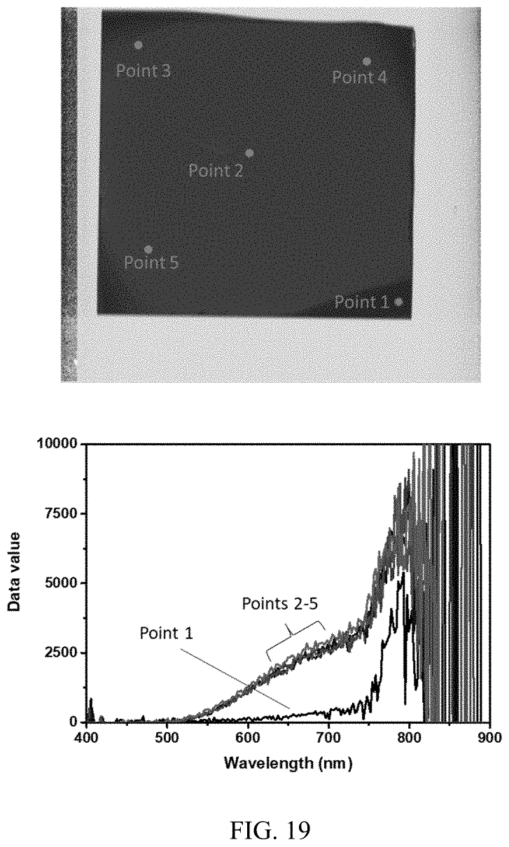

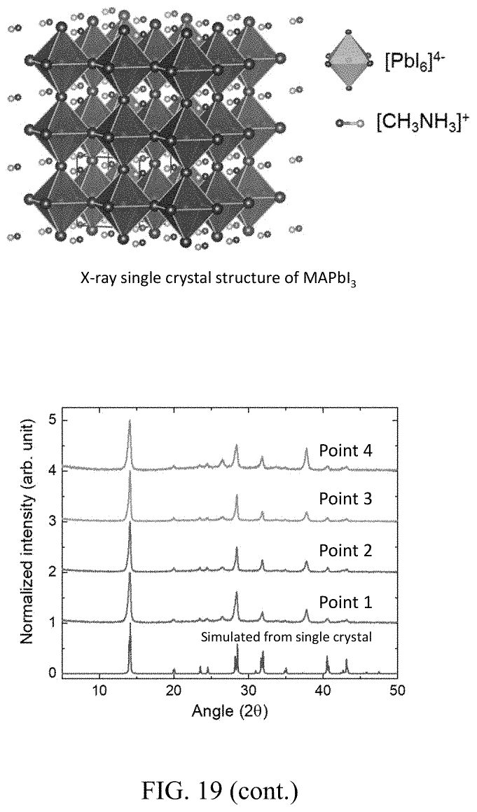

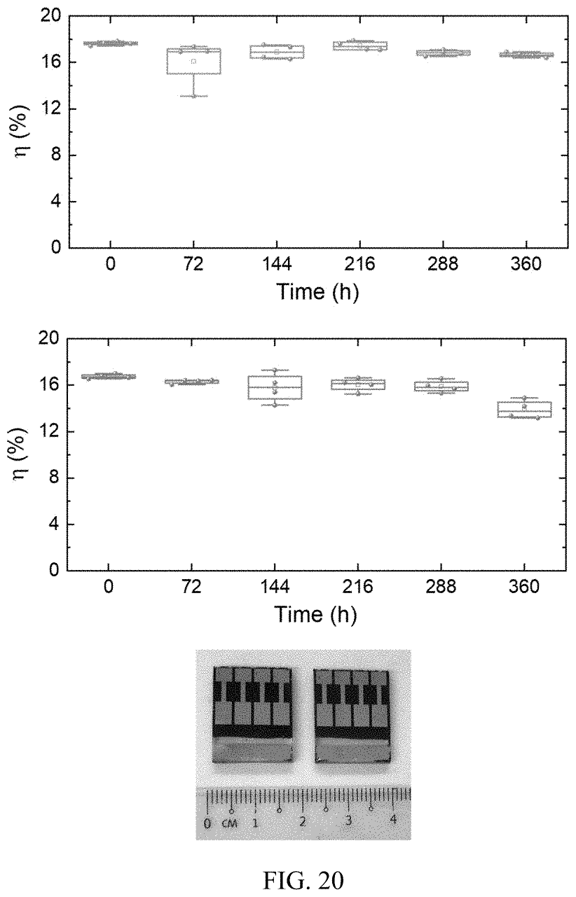

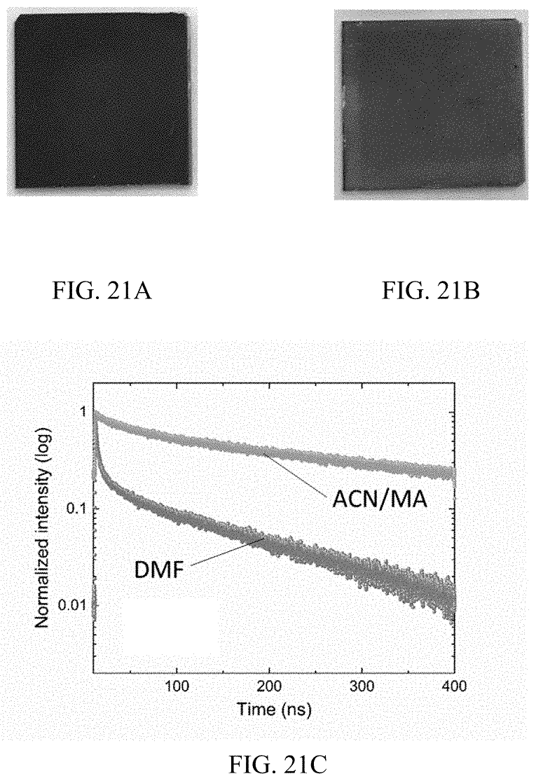

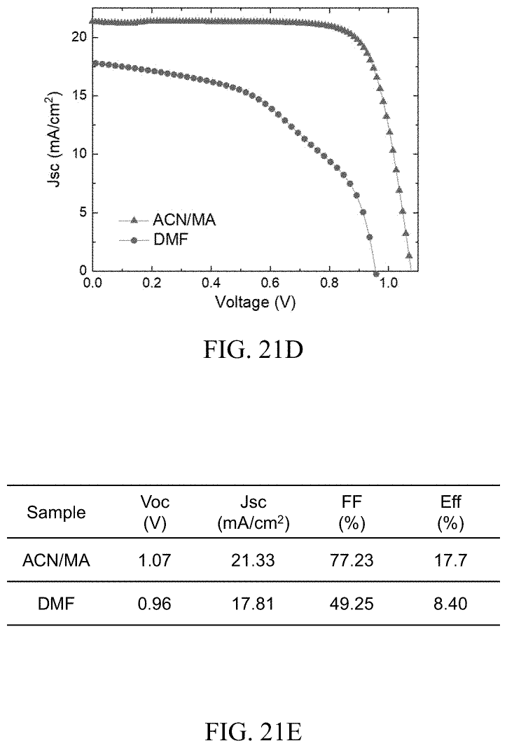

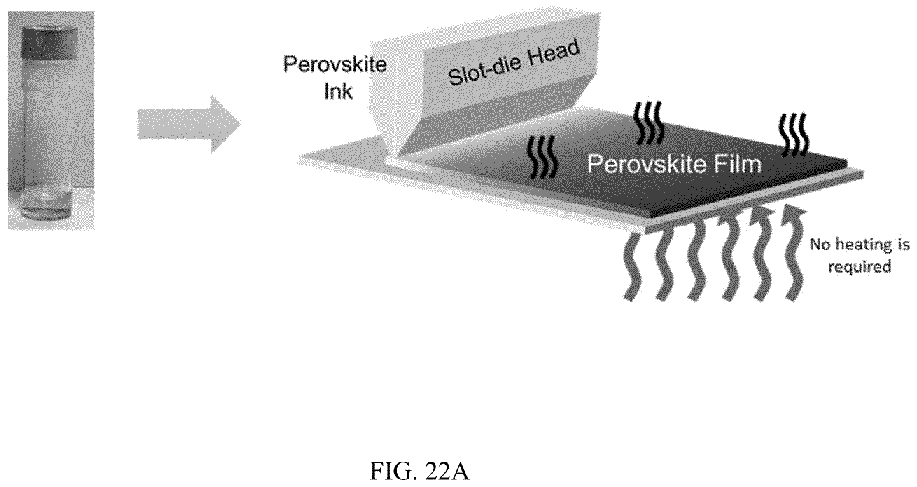

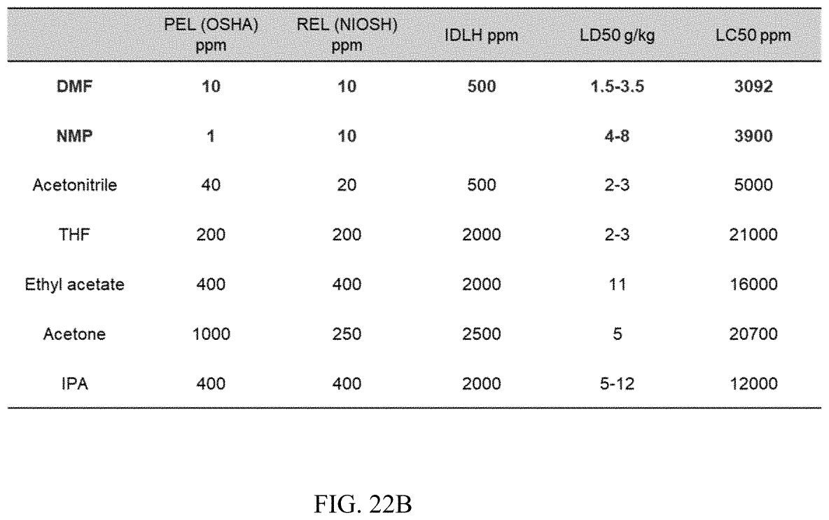

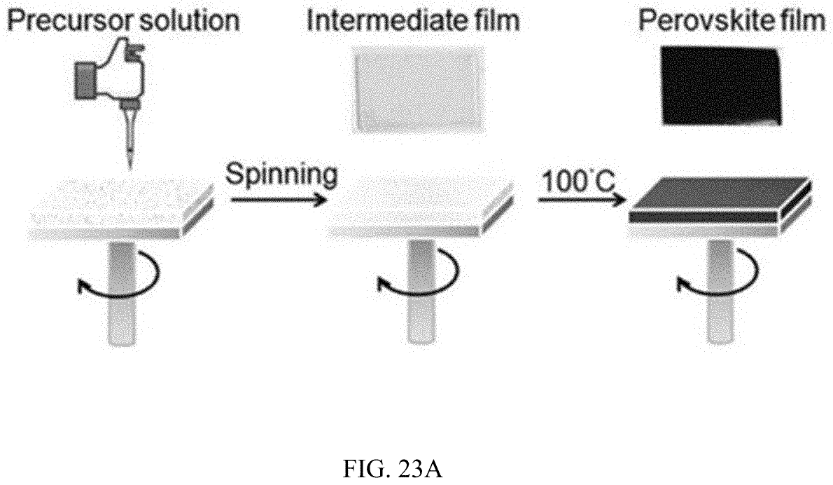

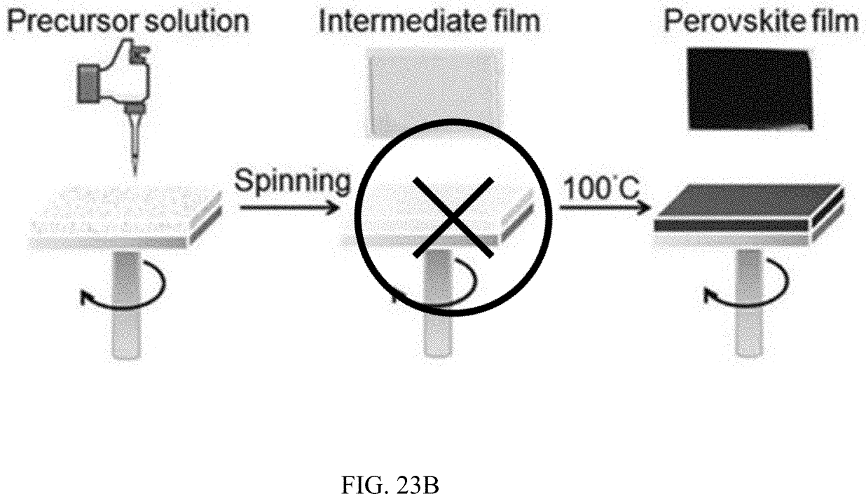

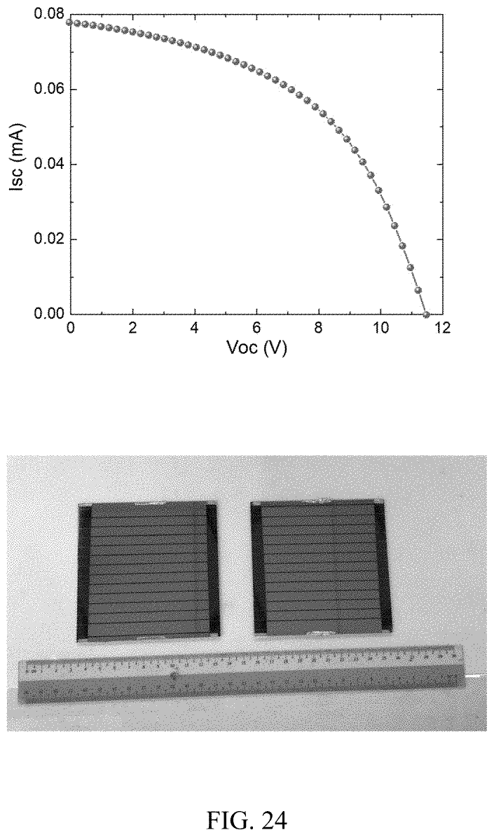

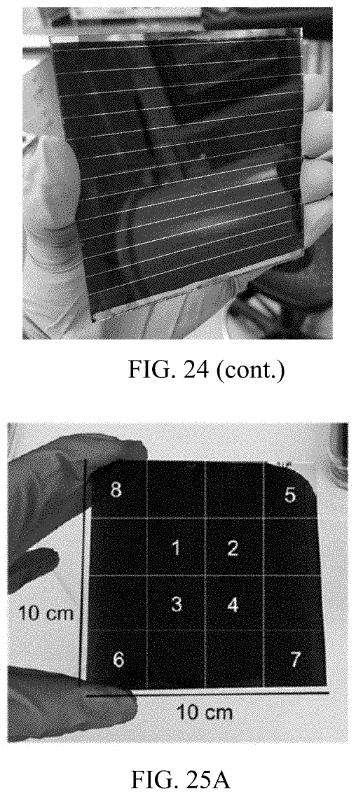

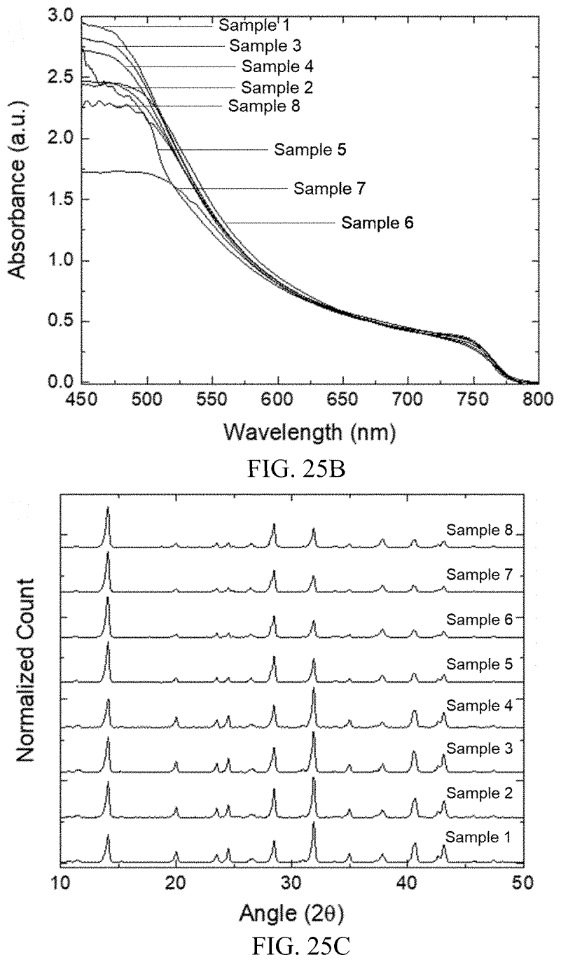

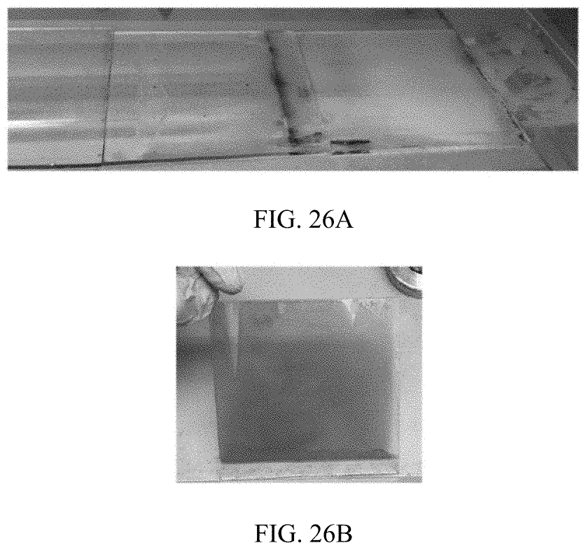

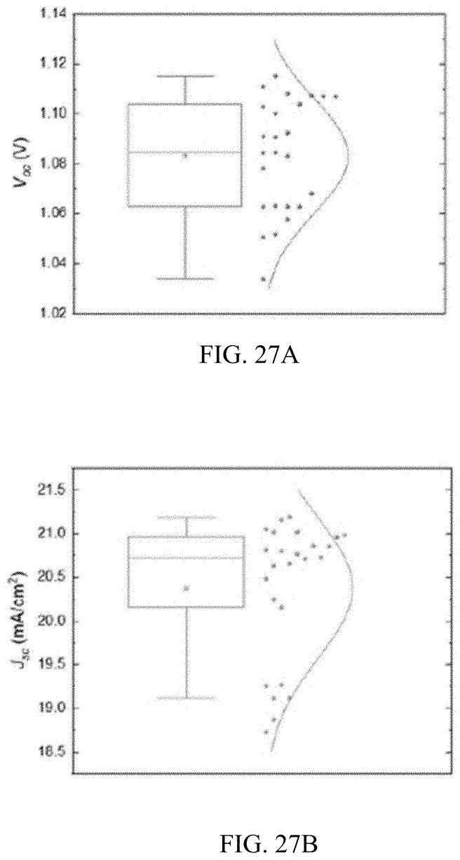

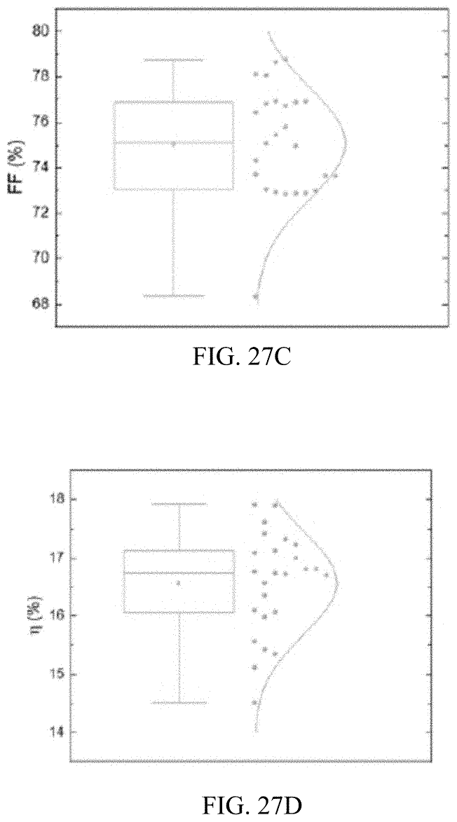

To ensure that the synthesis of CH₃NH₂—PbI₂ single crystals did not affect the quality of the precursor ink, fabrication of perovskite solar cells was then carried out with “n-i-p” configuration where planar tin oxide (SnO₂) and Spiro-OMeTAD were used as electron- and hole-transporting layers, respectively (FIG. 3A, FIG. 3B). A very thin layer of [6,6]-phenyl-C61-butyric acid methyl ester (PCBM) was, furthermore, used as passivation layer in the interface between SnO₂ and perovskite. Statistical representations of each photovoltaic parameter of resulting 25 devices are depicted in FIG. 3C and FIG. 15, which confirms the reproducibility of the device fabrication process. In particular, the devices fabricated with the perovskite ink yielded an average PCE of 16.60% with average open-circuit voltage (V_{OC}), short-circuit current density (J_{SC}), and fill-factor (FF) of 1.08 V, 20.38 mA cm⁻², and 75.08%, respectively, when measured under a simulated air mass (AM 1.5) of 1 sun illumination (100 mW cm⁻²).

Current density-voltage (J-V) characteristic of the best performing device is further presented in FIG. 3D. V_{OC}, J_{SC}, and FF of 1.110 V, 21.16 mA/cm², and 0.77, respectively, are observed in the reverse scan direction, yielding to PCE of 18.00%, while V_{OC}, J_{SC}, and FF of 1.105 V, 21.21 mA/cm², and 0.74, respectively, are recorded in the forward scan direction, resulting in PCE of 17.21%. Notably, these figures are on par with other reported MAPbI₃ devices fabricated from similar solvent system where pristine PbI₂ was used as starting precursor. This indicates that utilization of the as synthesized CH₃NH₂—PbI₂ in the precursor ink does not compromise the overall device performance. The corresponding typical IPCE spectrum that shows integrated J_{SC} of 20.52 mA/cm² is also shown in FIG. 3F, which highlights the consistency of current density being obtained from the fabricated devices.

The charge carrier recombination within the device was further investigated by measuring the light intensity dependent behavior (measured from 100 to 10 mW cm⁻²) of the device's J_{SC} and V_{OC}. The power law dependence profile of the J_{SC} with light intensity (J_{SC} ∝I^{α}, with I and a being the light intensity and the exponential factor, respectively) of the device is presented in FIG. 3F. Typically, good perovskite solar cells with no space charge effects show an a value close to 1, which indicates that charge collection efficiency was independent of light intensity. The device fabricated from the precursor ink resulted in slope of ca. 0.95, which suggests good perovskite crystal quality, charge carrier dissociation and reduced nonradiative recombinations in the solar cell. FIG. 3G further shows the dependence of V_{OC} on the illuminated light intensity (I). The diode ideality factor (n) is employed to describe the dependence of the voltage on the applied light intensity as illustrated by the following equation:

$$n = \frac{q}{2.303 {k}_{B} T} \times \frac{{dV}_{OC}}{dlog ( I )} \qquad ( 1 )$$

where n, k_{B}, q, and T are ideality factor, Boltzmann's constant, elementary charge, and temperature, respectively. Generally, the fitted n values are located at 1-2, which represents Shockley-Read-Hall trap-assisted recombination. In the present case, the device exhibits the n value of ca. 0.97, which suggests reduced trap-assisted recombination. This result is consistent with the conclusion from J-V curves where good V_{OC} of 1.11 V can be obtained.

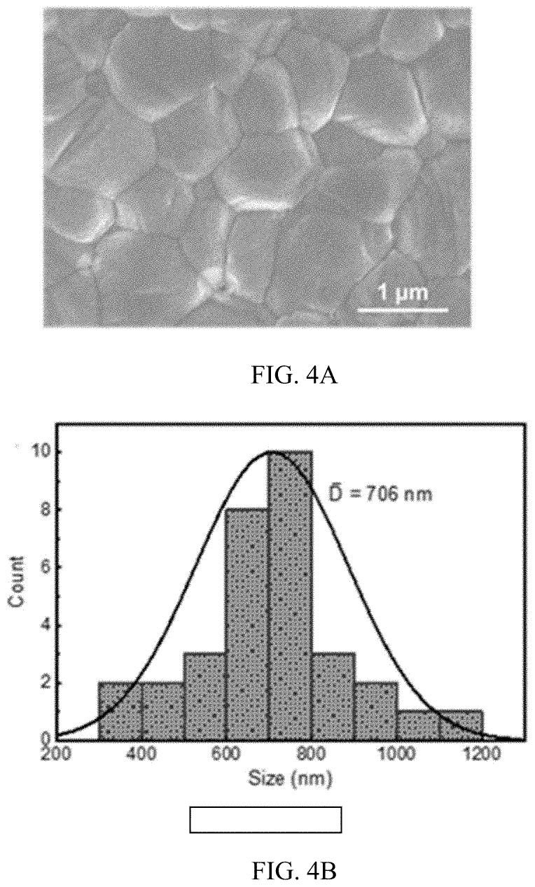

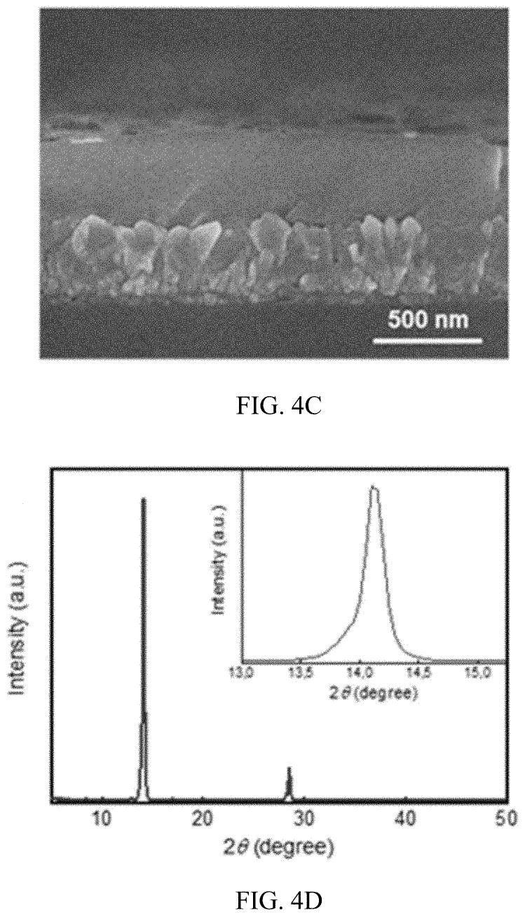

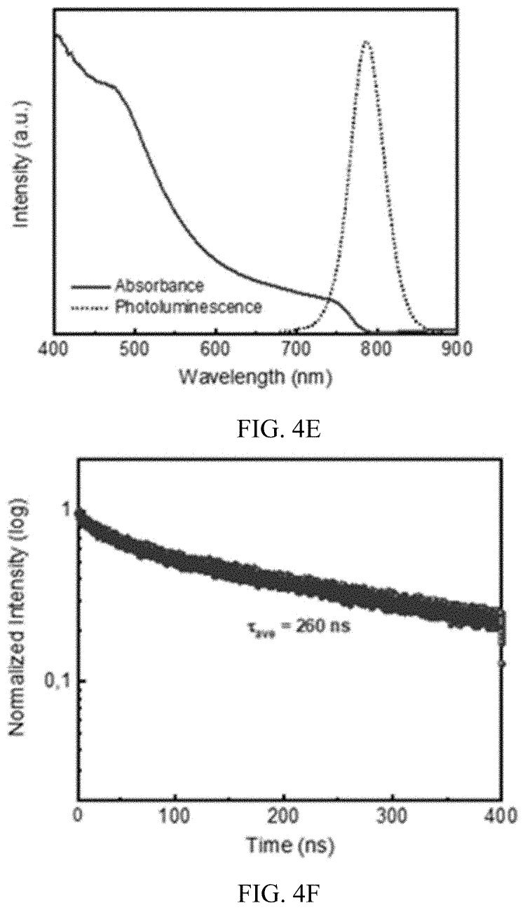

The high efficiency device obtained from the precursor ink can be ascribed to the facile perovskite crystallization in the absence of anti-solvent as well as the presence of CH₃NH₂ species in the solution which acts as reducing agent to the source of defects such as iodine or/and polyiodide species. The aforementioned two factors allow the formation of high quality perovskite films to be achieved, which are evident from the corresponding SEM images and glancing-angle X-ray diffraction pattern. As shown in FIG. 4A-FIG. 4D, the typical films feature uniform, compact perovskite crystallites with big grain sizes and of high crystallinity. In particular, densely packed crystal grains with the average size of individual domains of 706 nm are observed (FIG. 4B), together with strong and sharp (110) XRD peak with narrow full width at half maximum (FWHM) of ca. 0.181° (FIG. 4D, inset). The large grain size is believed to facilitate ease of charge carriers' extraction in the perovskite layer before collection in the electrode, while the high crystallinity feature is expected to feature reduced density of trap states in the bulk. The high quality of the perovskite films eventually lead to good optical properties of the material, characterized by sharp absorption edge (FIG. 4E, solid line), narrow PL band with FWHM of ca. 40 nm (FIG. 4E, dotted line), and relatively long PL lifetime of 260 ns (FIG. 4F). The relatively long PL lifetime decay, notably, corroborates with the big grain sizes observed as well as light dependent V_{OC} behavior in the fabricated device discussed previously.

Additional discussion for single crystal X-ray structure of [Pb(CH₃NH₂)I₂]ₙ. As mentioned before, the Pb′ ions in [Pb(CH₃NH₂)I₂]ₙ are five coordinate and the resulting square pyramids connect to one another via the bridging I-ions in edge- and vertex-sharing fashions. The latter sharing mode occurs at the turning of the ridge of the corrugation. The Pb—I bond distances involved in each corresponding mode are found to be 3.220 Å and 3.199 Å, respectively. These values are slightly shorter than that in PbI₂ (3.280 Å), but are elongated in comparison to those of MAPbI₃ (3.144−3.191 Å). Such coordination geometry exhibited by Pb′ in [Pb(CH₃NH₂)I₂]ₙ is very rare and we are aware of only one precedent report of hybrid iodide-based coordination polymer exhibiting similar geometry. The more common six coordinate are found, for examples, in coordination complexes of iodoplumbates with DMF, DMSO, or pyridines.

The overall supramolecular 3D network of 2D structures appear to be stabilized by weak hydrogen bonding between the NH₂ groups with the neighboring iodide ions at the adjacent layer (N . . . I contact of 3.899 Å). As mentioned, CH₃NH₂ organic coordinates strongly to the metal center with Pb—N bond distance being 2.452 Å. In comparison, the Pb—O bond distance in DMSO-coordinated iodoplumbate polymer is 2.491 Å, while Pb—N bond distances ranging from 2.547 Å to 2.714 Å are recorded for those based on pyridines. The observed stronger coordination can be associated with the stronger basicity of the N atom in CH₃NH₂, in comparison to the aforementioned organic ligands.

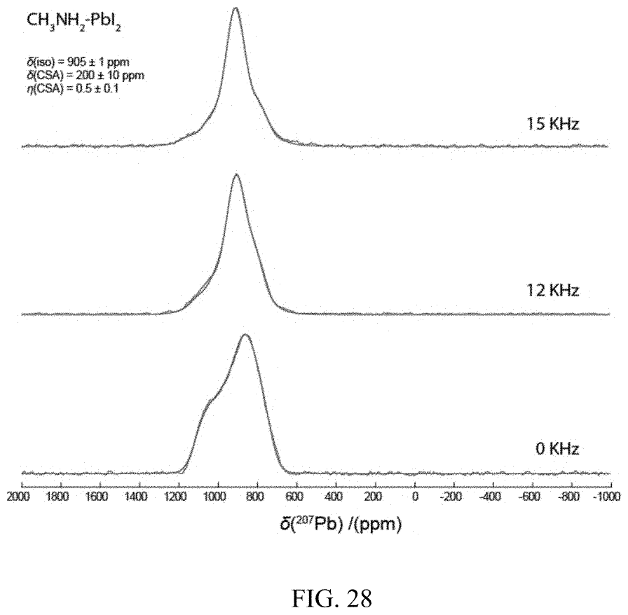

Additional discussion for ²⁰⁷Pb SS NMR spectrum of [Pb(CH₃NH₂)I₂]ₙ. Unlike PbI₂ and MAPbI₃ which exhibit Gaussian-shape resonance, [Pb(CH₃NH₂)I₂]ₙ presents an asymmetric lineshape as a result of the reduced symmetry about its Pb atom coordination geometry. Despite the asymmetry in its line-shape, however, the ²⁰⁷Pb NMR spectrum of [Pb(CH₃NH₂)I₂]ₙ still represents a single Pb environment and this has been accurately simulated via a single resonance (at 905 ppm) perturbed by chemical shift anisotropy (CSA). The CSA line-shape fitting was corroborated via acquisition and simulation at multiple magic-angle spinning (MAS) frequencies (FIG. 28). The presence of the CSA interaction in the resonance of [Pb(CH₃NH₂)I₂]ₙ is, as mentioned in the main text, a result of the reduced symmetry about the Pb atom, in comparison to the octahedral Pb—I configurations in PbI₂ and MAPbI₃. The increase in ²⁰⁷Pb chemical shift observed from PbI₂ through [Pb(CH₃NH₂)I₂]ₙ to MAPbI₃ is hypothesized to be a result of the decreasing Pb—I bond distances across the series. This is corroborated by a previous ²⁰⁷Pb SSNMR study of Pb²⁺ compounds with varying Pb—O bond lengths, which reasoned that the trend is due to increasing paramagnetic shielding with decreasing bond length.

### SUMMARY

In summary, the synthesis, isolation and characterizations of unprecedented RNH₂-MX₂ that features 2D structure is reported. It is a well-defined compound which has distinctive structural, spectroscopic, and physicochemical properties from commonly used perovskite precursor, MX₂. Notably, it serves as a “RNH₂-gas carrier” capable of liberating RNH₂ into precursor solution upon dissolution, thus improving the solubility of perovskite in nonconventional, relatively greener processing solvent, such as acetonitrile. The purity of the isolated RNH₂-MX₂ and the ability of RNH₂ to reduce sources of defects such as iodine or polyiodide species in solution allow the formation of high quality perovskite films. This eventually results in efficient and stable photovoltaic devices, fabricated via single step anti-solvent-free deposition method. Most importantly, this unique lead precursor can easily be prepared in a bulk and as such, is beneficial for preparation of large quantity perovskite ink in nonconventional solvent, which is essential for commercial practice in scaling-up of perovskite photovoltaic technology.

Additional Information

Chemicals. Lead(II) iodide (PbI₂) was obtained from TCI, while methylammonium thiocyanate (MA(SCN)) and methylammonium iodide (MAI) were from Greatcell Solar. Methylamine (CH₃NH₂) solution (33 wt. % in absolute ethanol (EtOH)), anhydrous ethyl acetate (EA), anhydrous acetonitrile (ACN), anhydrous chlorobenzene (CBZ), lithium bis(trifluoromethanesulfonyl)imide (LiTFSI), 4-tert-butylpyridine, and tin(II) chloride dihydrate were purchased from Sigma Aldrich. [6,6]-phenyl-C₆₁-butyric acid methyl ester (PCBM) was from Solenne BV and N2,N2,N2′,N2′,N7,N7,N7′,N7′-octakis(4-methoxyphenyl)-9,9′-spirobi[9H-fluorene]-2,2′,7,7′-tetramine (Spiro-OMeTAD) was from Lumtec. Unless otherwise stated, all reagents were used without purification.

X-ray crystallography. Single crystals were mounted on a Bruker X8 Quest CPAD area detector diffractometer and data was collected at 100 and 298 K using IμS 3.0 Microfocus Mo4 Kα radiation source (A=0.71073 Å). Data reduction and absorption corrections were performed using the SAINT and SADABS software packages, respectively. All structures were solved by direct methods and refined by full-matrix least squares procedures on F², using the Bruker SHELXTL-2014 software package. Non-hydrogen atoms were anisotropically refined, after which hydrogen atoms were introduced at calculated positions and subsequent further refinement of the data performed. Graphical representations of the crystal structures were created using the program VESTA.

Solid state (SS) NMR spectroscopy. All solid state NMR experiments in this study were completed on a Bruker Avance III HD 600 MHz spectrometer with a Bruker 4 mm HXY MAS probe. Spectral simulation of all NMR spectra was achieved via dmfit. The 207Pb NMR experiments were completed at 14.1 T (ν₀(²⁰⁷Pb)=125.55 MHz), employing a ²⁰⁷Pb Hahn echo pulse sequence with resulting data referenced with respect to 1.1M Pb(NO₃)_{2(aq)} (δᵢₛₒ=−2965.7 ppm). The ²⁰⁷Pb Hahn echo experiments utilised π/2 and π pulses of 5 and 10 μs, determined on Pb(NO₃)_{2(aq)}, with a recycle delay of 5 s. They were performed under MAS frequencies of 0 (static), 12 and/or 15 KHz with echo delays of 75.8, 75.8 and 59.2 μs, respectively. The ¹³C NMR experiments were completed at 14.1 T (ν₀(¹³C)=150.92 MHz) with an MAS frequency of 12 KHz. A ¹³C CPMAS pulse sequence was employed and resulting data was referenced with respect to adamantane (C₁₀H₁₆₍ₛ₎; δᵢₛₒ=38.48, 40.49 ppm). A ¹H π/2 pulse length of 2.3 μs, determined on adamantane, and a recycle delay of 10 s were used in the CPMAS experiments, alongside a contact pulse length of 4000 μs and high-power proton decoupling.

Nuclear Magnetic Resonance (NMR) spectroscopy, elemental analysis, mass spectrometry, and Fourier-Transform Infra-Red (FT-IR) spectroscopy. ¹³C{¹H} NMR spectra of the compounds were recorded, in CD₃CN solution, using a JEOL BBFO 400 MHz spectrometer. Chemical shift values (ppm) are referenced against residual protic solvent peaks. Elemental analyses were carried out using a PerkinElmer Series II CHNS/O analyzer. Mass spectra were recorded on JEOL-T100LP cold-spray ionization mass spectrometer using CSI negative ion modes. IR spectra was measured in transmission mode using a VERTEX 80V FTIR spectrophotometer in the wavenumber range 4000-400 cm⁻¹ with resolution of 4 cm⁻¹ under reduced pressure (10⁻⁵ Torr).

UV-vis spectroscopy and field-emission scanning electron microscopy (FE-SEM). UV-vis absorption spectra of perovskite thin films were recorded in the wavelength range 300-800 nm, using a SHIMADZU UV-3600 spectrophotometer, with an integrating sphere (ISR-3100). Surface morphology images of the perovskite thin film samples were recorded using a JEOL JSM-7600F field emission scanning electron microscope (FESEM), with an accelerating voltage of 5 kV.

Temperature- and power-dependent photoluminescence spectroscopies. Time-resolved and steady state photoluminescence measurements were conducted using a micro-PL setup utilizing a Nikon objective microscope (20× magnification, NA=0.3) with a picosecond-pulsed laser diode (Picoquant P-C-405B; =405 nm, f=40 MHz) as the excitation source. For the time-resolved measurements the Picoquant PicoHarp 300 time-correlated single photon counting (TCSPC) set-up was used, with the output signal coupled to an Acton SP-2300i monochromator (300 mm focal length) for spectral selection of the emission wavelength. Another optical fiber connected to the output of the monochromator was used to couple spectral separated output light to an avalanche diode synchronized with the excitation laser via the TCSPC electronics. For the steady state measurements, the optical fiber was connected to the output of the monochromator, whereas the spectrally separated light was collected by a photomultiplier (PMT, Hamamatsu).

Powder and glancing angle X-ray diffraction. Powder and glancing-angle X-ray diffraction measurements were conducted using a Bruker AXS D8 ADVANCE system with Cu Kα radiation (λ=1.5418 Å). The XRD spectra were recorded with an incident angle of 5°, a step size of 0.05°, and a delay time of is for each step. The measurements were carried out with the samples being in the domed-sample holder (prepared previously inside of the argon-filled glovebox) to prevent the exposure to H₂O and O₂.

Solar cell devices and incident photon-to-current efficiencies. Photovoltaic characteristics of the solar cell devices were measured in the reverse scanning direction (from Voc to J_{SC}), with a sweep rate of 100 mV/s, under AM1.5G (100 mW/cm²) spectral irradiation from a solar simulator (Newport 91190 Å) incorporating a 450 W xenon lamp (model 81172, Oriel) calibrated with a Si reference cell (Oriel PN91150). Devices were characterized through a 0.08 cm² black mask. Incident photon-to-current efficiency (IPCE) was measured using a photovoltaic quantum efficiency (QE) instrument, PVE300 (Bentham), with a dual xenon/quartz halogen light source, measured in DC mode, and no bias light was used in the wavelength range 300-800 nm. A Coherent OPerA Solo optical parametric amplifier pumped with a regenerative amplifier (50 fs, 1 kHz, 800 nm) was used to generate a 600 nm excitation beam.

Growth and isolation of single crystals of hybrid 2D CH₃NH₂—PbI₂. All of the following steps are carried out in argon-filled glovebox (O₂ & H₂O<0.1 ppm). Stoichiometric amounts of PbI₂ and MAI (1:1) in a vial of suitable size were added to anhydrous EA before the mixture was vortexed for 5-10 minutes to ensure uniform mixing. CH₃NH₂ in EtOH was then added into the suspension before another round vortexing for 5-10 minutes, to result in a final clear solution with concentration of 0.50 M. The resulting solution was then let to stand still in a disturbance free space. Typically, big single crystals suitable for X-ray crystallography can be afforded within 24 hours of growing. For isolation of single crystals, the growing time is typically 2-3 days, in which the solvents were carefully and thoroughly removed via decantation before the crystals were further dried in vacuo. (24.67 g; 79% based on Pb²⁺). Elemental Analysis Calcd (Found) for CH₅I₂NPb: C, 2.27 (2.44); H, 1.18 (1.02); N, 2.69 (2.85).

Preparation of perovskite ink containing CH₃NH₂—PbI₂ (FIG. 15). CH₃NH₂—PbI₂, MAI, and additional 5 mole % of MA(SCN), relative to Pb²⁺, were initially mixed in anhydrous ACN (typical concentration of ˜0.50 M). The resulting mixture was stirred to ensure complete reaction between MAI and CH₃NH₂—PbI₂ and complete release of CH₃NH₂ into the solution. Additional CH₃NH₂ gas is then introduced through this mixture via the following method: briefly, a solution of CH₃NH₂ in EtOH was firstly placed into a gas washing bottle which was kept in an ice bath to prevent H₂O or EtOH from passing into the perovskite precursor. A carrier gas of argon was then allowed to go through the solution, controlled using a gas regulator, thus degassing the solution of CH₃NH₂. The bubbled CH₃NH₂ gas was then passed through a drying tube containing desiccants Drierite and CaO, before bubbling into the ACN mixture of perovskite precursors, leading to a clear yellow solution. Due to the high relative humidity of a typical laboratory in Singapore, throughout the bubbling process, the perovskite ink is not exposed to ambient condition (i.e. vials or round bottomed flasks capped with rubber septa). The resulting solutions were then transferred into an argon-filled glovebox (O₂ & H₂O<0.1 ppm) for the remainder of the fabrication processes.

Thin film fabrication. Thin films used in optical and morphological characterizations were prepared by the following procedure which is carried out in an argon-filled glovebox (O₂ & H₂O<0.1 ppm). Typically, 0.50 M ACN solutions of stoichiometric amounts of CH₃NH₂—PbI₂ and MAI, with 5 mol % MA(SCN) (relative to Pb²⁺), were spin coated, at 4000 rpm for 120 s, onto pre-etched fluorine-doped tin oxide (FTO)-patterned substrates. (The substrates were cleaned by sequential 15 minute sonication in Hellmanex detergent solution (2% v/v in deionized water), deionized water, acetone, ethanol, and isopropanol, followed by ozone plasma treatment for 30 mins.) In order to remove residual solvents, the resulting films were then heated at 100° C. for 45 mins.

Solar cell device fabrication. Pre-etched FTO glass substrates (TEC-15) were washed under sonication in: Hellmanex detergent solution (2% v/v in deionized water), deionized water, acetone, ethanol, and in isopropanol, consecutively. The substrates were dried and treated for 30 mins by ozone plasma. Separately, 50 mM SnCl₂.2H₂O solution in EtOH was prepared and spincoated using a two-step program at 1500 rpm for 10 s, followed by 5000 rpm for 10 s. The substrate was then preheated at 80° C. for 30 min and subsequently heated to 180° C. for 1 h in air to completely oxidize the SnCl₂ to SnO₂. The substrates were then transferred into an argon-filled glovebox (O₂ & H₂O<0.1 ppm) for the remainder of the fabrication processes.

A layer of PCBM (2 mg/mL in CBZ) was spincoated onto the perovskite film at 4000 rpm for 30 s, followed by annealing at 100° C. for 10 mins. Once cooled to room temperature, 0.50 M ACN solutions of stoichiometric amounts of CH₃NH₂—PbI₂ and MAI, with or without 5 mol % (relative to Pb²⁺), were spin coated, at 4000 rpm for 120 s, followed by annealing at 100° C. for 45 mins. The Spiro-OMeTAD layer was then deposited by spincoating its solution (Spiro-OMeTAD (72 mg/mL in CBZ) with addition of 4-TBP (28.5 μL) and LiTFSI (17.5 μL; taken from stock ACN solution with concentration of 520 mg/mL)) dynamically at 4000 rpm for 30 s. Finally, gold (Au) electrode was thermally evaporated under high vacuum (10⁻⁶ Torr) to achieve a thickness of ca. 100 nm through a metal shadow mask (active area of 0.2 cm².)

TABLE 1
Crystallographic and structure refinement data for
CH₃NH₂—PbI₂ at ambientand cryogenic temperatures.^{a}

| | Compound | | | |
|---|---|---|---|---|
| | CH₃NH₂—PbI₂ (RT) | | CH₃NH₂—PbI₂ (100K) | |
| Empirical formula | CH₅I₂NPb | | CH₅I₂NPb | |
| Formula weight | 492.05 | g/mol | 492.05 | g/mol |
| Wavelength | 0.71073 | Å | 0.71073 | Å |
| Crystal size | 0.020 × 0.040 × 0.060 mm³ | | 0.120 × 0.200 × 0.220 mm³ | |
| Crystal habit | yellow block | | orange block | |
| Crystal system | orthorhombic | | orthorhombic | |
| Space group | C m c a | | C m c a | |
| Unit cell dimensions | a = | 8.8397(7) Å | a = | 8.7746(5) Å |
| | α = | 90° | α = | 90° |
| | b = | 19.7094(18) Å | b = | 19.2817(12) Å |
| | β = | 90° | β = | 90° |
| | c = | 8.4762(6) Å | c = | 8.4744(5) Å |
| | γ = | 90° | γ = | 90° |
| Volume | 1476.8(2) | Å³ | 1433.78(15) | Å³ |
| Z | 8 | | 8 | |
| Density | 4.426 | g/cm³ | 4.559 | g/cm³ |
| Absorption coefficient | 31.092 | mm⁻¹ | 32.024 | mm⁻¹ |
| F(000) | 1648 | | 1648 | |
| Theta range for data | 3.17 to 30.07° | | 3.20 to 31.00° | |
| collection | | | | |
| Reflections collected | 8371 | | 5870 | |
| Coverage of independent | 99.90% | | 99.90% | |
| reflections | | | | |
| Absorption correction | Multi-Scan | | Multi-Scan | |
| Max. and min. transmission | 0.5750 and 0.2570 | | 0.1140 and 0.0540 | |
| Function minimized | Σ w(Fₒ² − F_{c}²)² | | Σ w(Fₒ² − F_{c}²)² | |
| Data/restraints/parameters | 1153/0/29 | | 1217/0/30 | |
| Goodness-of-fit on F² | 1.036 | | 1.095 | |
| Δ/σmax | 0.001 | | 0.001 | |
| Final R indices | 822 | data | 1099 | data |
| [I > 2σ(I)] | R1 = | 0.0382, | R1 = | 0.0249, |
| | wR2 = | 0.0673 | wR2 = | 0.0506 |
| R indices [all data] | R1 = | 0.0685, | R1 = | 0.0290, |
| | wR2 = | 0.0769 | wR2 = | 0.0523 |
| Largest diff. peak and hole | 1.483 and −1.832 | eÅ⁻³ | 1.818 and −1.671 | eÅ⁻³ |
| R.M.S. deviation from mean | 0.322 | eÅ⁻³ | 0.306 | eÅ⁻³ |

^{a}R = Σ||Fₒ| − |F_{c}||/Σ|Fₒ|, wR = {Σ[w(|Fₒ|² − |F_{c}|²)²/Σ[w(|Fₒ|⁴)]}^{1/2} and CH₃NH₂—PbI₂ at RT, w = 1/[σ²(Fₒ²) + (0.0239 P)² + 26.7833 P]; CH₃NH₂—PbI₂ at 100K, w = 1/[σ²(Fₒ²) +(0.0209 P)² where P = (Fₒ² + 2F_{c}²)/3.

TABLE 2
Summary of the time-resolved
photoluminescence (TRPL)
parameters of the perovskite films.

| Parameters | Lifetime | |
|---|---|---|
| PL decay τ₁ (ns) | 39 | (31%) |
| PL decay τ₂ (ns) | 360 | (69%) |

| | |
|---|---|
| PL decay τₐᵥₑ (ns) | 261 |

While the disclosure has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

1. An organic metal-halide perovskite precursor comprising a divalent metal cation, a halide anion, and an alkylamine, wherein the divalent metal cation is connected to a nitrogen atom of the alkylamine via a covalent bond.

2. The organic metal-halide perovskite precursor of claim 1, wherein the organic metal-halide perovskite precursor is present in the form of polymeric layers.

3. The organic metal-halide perovskite precursor of claim 1, wherein the organic metal-halide perovskite precursor is thermally stable up to a temperature of at least 50° C.

4. The organic metal-halide perovskite precursor of claim 1, wherein the divalent metal cation is a five-coordinate metal center in a square pyramid coordination.

5. The organic metal-halide perovskite precursor of claim 1, wherein the covalent bond has a length of less than 4 angstrom (Å).

6. The organic metal-halide perovskite precursor of claim 1, wherein the organic metal-halide perovskite precursor is of the general structure:
RNH₂-MX₂ Formula (I)
wherein:
R is an organic moiety;
M is the divalent metal cation; and
X is the halide anion.

7. The organic metal-halide perovskite precursor of claim 6, wherein R is a linear or branched, substituted or unsubstituted C₁-C₁₀ alkyl; linear or branched, substituted or unsubstituted C₂-C₁₀ alkenyl; linear or branched, substituted or unsubstituted C₂-C₁₀ alkynyl; linear or branched, substituted or unsubstituted C₁-C₁₀ alkoxy; substituted or unsubstituted C₃-C₁₀ cycloalkyl; substituted or unsubstituted C₃-C₁₀ cycloalkenyl; substituted or unsubstituted C₆-C₁₀ aryl; substituted or unsubstituted C₃-C₁₀ heteroaryl.

8. The organic metal-halide perovskite precursor of claim 6, wherein R is a linear or branched, substituted or unsubstituted C₁-C₁₀ alkyl.

9. The organic metal-halide perovskite precursor of claim 6, wherein X is an iodide.

10. The organic metal-halide perovskite precursor of claim 6, wherein M is any divalent metal cation of group 14.

11. The organic metal-halide perovskite precursor of claim 10, wherein the divalent metal cation of group 14 is a lead cation.

12. A process for the production of an organic metal-halide perovskite precursor comprising a divalent metal cation, a halide anion and an alkylamine, wherein a covalent bond connects the divalent metal cation to a nitrogen atom of the alkylamine, the process comprising:
a) forming a solution comprising an organic solvent system and following reagents dissolved therein:
a first salt of the divalent metal cation with the halide anion;
a second salt of an alkylammonium cation with the halide anion; and
the alkylamine; and
b) crystallizing the organic metal-halide perovskite precursor from the solution.

13. The process of claim 12, wherein step a) further comprises preparing a precursor solution from the first salt and the second salt, both dissolved in a first organic solvent.

14. The process of claim 13, wherein step a) further comprises adding the alkylamine dissolved in a second organic solvent to the precursor solution.

15. The process of any of claim 12, wherein step b) comprises the crystallization to be carried out substantially disturbance-free.

16. The process of any of claim 12, wherein the solution has a concentration of the divalent metal cation of at least 0.4 M.

17. The process of any of claim 12, wherein step b) further comprises separating the organic metal-halide perovskite precursor from the solution.

18. A perovskite ink comprising the organic metal-halide perovskite precursor of claim 1 or a perovskite solution comprising the divalent metal cation, the halide anion, and the alkylamine; and a non-coordinating solvent, wherein the organic metal-halide perovskite precursor is dissolved in the non-coordinating solvent, and wherein the alkylamine is optionally liberated from the organic metal-halide perovskite precursor to give the perovskite solution.

19. The perovskite ink or the perovskite solution of claim 18, wherein the non-coordinating solvent is selected from the group consisting of acetonitrile, tetrahydrofuran, acetone, ethyl acetate, alcohol, and a combination thereof.

20. A perovskite comprising a divalent metal cation, a halide anion, and an alkylamine, prepared from a perovskite ink or the perovskite solution of claim 18.
